(19) United States
(12) Patent Application Publication
(10) Pub. No.: US 2011/0108818 A1
(43) Pub. Date: May 12, 2011

(54) ORGANIC ELECTROLUMINESCENCE DEVICE

(75) Inventors: Joachim Kaiser, Darmstadt (DE); Arne Buesing, Frankfurt (DE); Anja Gerhard, Veitschochheim (DE); Philipp Stoessel, Frankfurt (DE); Susanne Heun, Bad Soden (DE)

(73) Assignee: Merck Patent GmbH, Darmstadt (DE)

(21) Appl. No.: 13/000,885

(22) PCT Filed: Nov. 18, 2009
(86) PCT No.: PCT/EP09/08196

§ 371 Date: Dec. 22, 2010

(30) Foreign Application Priority Data
Dec. 17, 2008 (DE) 10 2008 063 470.3

(51) Int. Cl. H01L 51/54

(52) U.S. Cl. 257/40; 257/E51.028; 257/E51.029

(57) ABSTRACT

The present invention relates to organic electroluminescent devices which comprise ketone or phosphine oxide derivatives as matrix material and at least two phosphorescent compounds.

The present invention relates to phosphorescent organic electroluminescent devices which comprise two phosphorescent dopants.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. However, further improvements are still necessary. Thus, there is still a need for improvement with respect to the lifetime, the efficiency and the operating voltage of organic electroluminescent devices. There also continues to be a need for improvement, in particular, in the so-called roll-off behaviour of OLEDs, i.e. the efficiency as a function of the luminance of the OLED, since it is frequently observed that the efficiency drops considerably at high luminance. This applies, in particular, to electroluminescent devices which are doped with a phosphorescent emitter.

In accordance with the prior art, carbazole derivatives, for example bis-(carbazolyl)biphenyl, are frequently used as matrix material for the phosphorescent emitter. There is still a need for improvement here, in particular with respect to the efficiency and the lifetime of the OLEDs produced with these materials. In addition, these matrix materials frequently result in comparatively high operating voltages.

In accordance with the prior art, electron-conducting materials, inter alia ketones (for example in accordance with WO 04/093207 or in accordance with the unpublished application DE 102008033943.1), phosphine oxides and sulfones (WO 05/003253), are furthermore used as matrix materials for phosphorescent emitters. Very low operating voltages and long lifetimes are achieved, in particular, with ketones, possibly owing to the good electron-transport properties, which makes this class of compounds a very interesting matrix material. However, there is still a need for improvement on use of these matrix materials, in particular with respect to the efficiency. Furthermore, these matrix materials frequently result in stronger roll-off behaviour of the OLED, i.e. a greater drop in efficiency at high luminance than with other matrix materials. There is therefore still a need for improvement here. Furthermore, these matrix materials in some cases exhibit incompatibility with metal complexes containing ketoketonate ligands, for example acetylacetonate. This is evident from lower efficiency and a shorter lifetime. However, these metal complexes in particular have proven themselves as emitters having very good emission properties, and consequently many of the phosphorescent emitters used at present are of this structural type. There therefore continues to be a need for improvement here.

The technical object on which this invention is based is therefore the provision of an organic electroluminescent device which exhibits reduced roll-off behaviour at high luminance. A further object is the provision of an organic electroluminescent device which comprises a metal complex containing ketoketonate ligands and which, with this dopant, results in good emission properties, in particular good efficiency, a long lifetime and a low operating voltage.

Surprisingly, it has been found that organic electroluminescent devices which comprise, in the emitting layer, an aromatic ketone or an aromatic phosphine oxide or another matrix material of those defined below which is substituted by two different phosphorescent emitters simultaneously exhibit high efficiencies, long lifetimes and low operating voltages, even with phosphorescent emitters which contain ketoketonate ligands. Furthermore, these electroluminescent devices exhibit surprisingly little roll-off, enabling them also to be operated with good efficiency at high luminance.

The prior art discloses organic electroluminescent devices which comprise two phosphorescent emitters in a matrix.

US 2007/0247061 discloses organic electroluminescent devices which comprise one host material and two phosphorescent dopants. In the examples, the only matrix material indicated is CBP (bis(carbazolyl)-biphenyl). However, these electroluminescent devices have very high operating voltages. The voltages here are comparable or even higher than in electroluminescent devices which comprise only one phosphorescent dopant. An influence on the roll-off behaviour of the electroluminescent device is not disclosed.

US 2002/0125818 discloses organic electroluminescent devices which comprise a host material, a phosphorescent dopant and a fluorescent or phosphorescent dopant which emits at longer wavelengths. Triarylamine derivatives and carbazole derivatives, in particular, are disclosed as host material. Better efficiencies and, especially for the combination with a fluorescent dopant, also a better lifetime are achieved therewith. An influence on the lifetime is not disclosed for electroluminescent devices which comprise two phosphorescent dopants. Furthermore, an influence on the roll-off behaviour of the electroluminescent device is not disclosed either.

The invention thus relates to an organic electroluminescent device comprising, in at least one emitting layer,
(A) a phosphorescent compound A,
(B) a phosphorescent compound B which is different from phosphorescent compound A, and
(C) a matrix material selected from the group consisting of aromatic ketones, aromatic phosphine oxides, aromatic sulfoxides and aromatic sulfones.

For the purposes of this application, an aromatic ketone is taken to mean a carbonyl group to which two aromatic or heteroaromatic groups or aromatic or heteroaromatic ring systems are bonded directly. For the purposes of this application, an aromatic phosphine oxide is taken to mean a P═O group to which three aromatic or heteroaromatic groups or aromatic or heteroaromatic ring systems are bonded directly. For the purposes of this application, an aromatic sulfoxide is taken to mean an S═O group to which two aromatic or heteroaromatic groups or aromatic or heteroaromatic ring systems are bonded directly. For the purposes of this application, an aromatic sulfone is taken to mean an S(═O)₂ group to which two aromatic or heteroaromatic groups or aromatic or heteroaromatic ring systems are bonded directly.

Preference is given to an organic electroluminescent device comprising, in at least one emitting layer,
(A) at least one phosphorescent compound A,
(B) a phosphorescent compound B which is different from phosphorescent compound A, and
(C) at least one compound selected from the compounds of the formula (1)

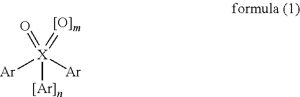

where the following applies to the symbols and indices used:
X is C, P or S;
Ar is on each occurrence, identically or differently, an aromatic or heteroaromatic ring system having 5 to 80 aromatic ring atoms, which may in each case be substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkenyl, alkynyl, alkoxy or thioalkoxy group having 1 to 40 C atoms or a branched or cyclic alkyl, alkenyl, alkoxy or thioalkoxy group having 3 to 40 C atoms, each of which may be substituted by one or more radicals R², where one or more non-adjacent CH₂ groups may be replaced by R²C═CR², C≡O, Si(R²)₂, Ge(R²)₂, Sn(R²)₂, C═O, C═S, C═Se, C═NR², P(═O)(R²), SO, SO₂, NR², O, S or CONR² and where one or more H atoms may be replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which may be substituted by one or more radicals R², or an aralkyl or heteroaralkyl group having 5 to 60 aromatic ring atoms, which may be substituted by one or more radicals R², or a combination of these systems; two or more adjacent substituents R¹ here may also form a mono- or polycyclic, aliphatic or aromatic ring system with one another;
Ar¹ is on each occurrence, identically or differently, an aromatic or heteroaromatic ring system having 5 to 40 aromatic ring atoms, which may be substituted by one or more radicals R²;
R² is on each occurrence, identically or differently, H, D or an aliphatic, aromatic and/or heteroaromatic organic radical, in particular a hydrocarbon radical having 1 to 20 C atoms, in which, in addition, H atoms may be replaced by F; two or more adjacent substituents R² here may also form a mono- or polycyclic, aliphatic or aromatic ring system with one another;
n is 0 for X═C or S and is 1 for X═P;
m is 0 for X═C or P and is 0 or 1 for X═S.

In a preferred embodiment of the invention, neither Ar nor Ar¹ contains a triarylamine group or a carbazole group.

An organic electroluminescent device is taken to mean a device which comprises an anode, a cathode and at least one emitting layer which is arranged between the anode and the cathode, where at least one layer between the anode and the cathode comprises at least one organic or organometallic compound. At least one emitting layer here comprises at least one phosphorescent emitter A, at least one phosphorescent emitter B and at least one compound of the formula (1) given above. An organic electroluminescent device does not necessarily have to comprise only layers built up from organic or organometallic materials. Thus, it is also possible for one or more layers to comprise inorganic materials or to be built up entirely from inorganic materials.

For the purposes of this invention, a phosphorescent compound is a compound which exhibits luminescence from an excited state having relatively high spin multiplicity, i.e. a spin state>1, in particular from an excited triplet state, at room temperature. For the purposes of this invention, all luminescent transition-metal complexes, in particular all luminescent iridium and platinum compounds, are to be regarded as phosphorescent compounds.

For the purposes of this invention, an aryl group contains at least 6 C atoms; for the purposes of this invention, a heteroaryl group contains at least 2 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed aryl or heteroaryl group, for example naphthalene, anthracene, pyrene, quinoline, isoquinoline, etc.

For the purposes of this invention, an aromatic ring system contains at least 6 C atoms in the ring system. For the purposes of this invention, a heteroaromatic ring system contains at least 2 C atoms and at least one heteroatom in the ring system, with the proviso that the sum of C atoms and heteroatoms is at least 5. The heteroatoms are preferably selected from N, O and/or S. For the purposes of this invention, an aromatic or heteroaromatic ring system is intended to be taken to mean a system which does not necessarily contain only aryl or heteroaryl groups, but instead in which a plurality of aryl or heteroaryl groups may also be interrupted by a short non-aromatic unit (preferably less than 10% of the atoms other than H), such as, for example, an sp³-hybridised C, N or O atom. Thus, for example, systems such as 9,9′-spirobifluorene, 9,9-diarylfluorene, triarylamine, diaryl ether, stilbene, benzophenone, etc., are also intended to be taken to mean aromatic ring systems for the purposes of this invention. Likewise, an aromatic or heteroaromatic ring system is taken to mean systems in which a plurality of aryl or heteroaryl groups are linked to one another by single bonds, for example biphenyl, terphenyl or bipyridine.

For the purposes of the present invention, a C₁- to C₄₀-alkyl group, in which, in addition, individual H atoms or CH₂ groups may be substituted by the above-mentioned groups, is particularly preferably taken to mean the radicals methyl, ethyl, n-propyl, i-propyl, n-butyl, i-butyl, s-butyl, t-butyl, 2-methylbutyl, n-pentyl, s-pentyl, tert-pentyl, 2-pentyl, cyclopentyl, n-hexyl, s-hexyl, tert-hexyl, 2-hexyl, 3-hexyl, cyclohexyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]octyl, 2-(2,6-dimethyl)octyl, 3-(3,7-dimethyl)octyl, trifluoromethyl, pentafluoroethyl and 2,2,2-trifluoroethyl. An alkenyl group is particularly preferably taken to mean the radicals ethenyl, propenyl, butenyl, pentenyl, cyclopentenyl, hexenyl, cyclohexenyl, heptenyl, cycloheptenyl, octenyl and cyclooctenyl. An alkynyl group is particularly preferably taken to mean the radicals ethynyl, propynyl, butynyl, pentynyl, hexynyl, heptynyl and octynyl. A C₁- to C₄₀-alkoxy group is particularly preferably taken to mean methoxy, trifluoromethoxy, ethoxy, n-propoxy, i-propoxy, n-butoxy, i-butoxy, s-butoxy, t-butoxy or 2-methylbutoxy. An aromatic or heteroaromatic ring system having 5-60 aromatic ring atoms, which may in each case also be substituted by the above-mentioned radicals R and which may be linked via any desired positions on the aromatic or heteroaromatic ring system, is taken to mean, in particular, groups derived from benzene, naphthalene, anthracene, phenanthrene, benzanthracene, benzophenanthrene, pyrene, chrysene, perylene, fluoranthene, benzofluoranthene, naphthacene, pentacene, benzopyrene, biphenyl, biphenylene, terphenyl, terphenylene, fluorene, benzofluorene, dibenzofluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, iso-benzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diaza-pyrene, 2,3-diazapyrene, 1,6-diazapyrene, 1,8-diazapyrene, 4,5-diaza-pyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The compounds of the formula (1) preferably have a glass-transition temperature T_{G} of greater than 70° C., particularly preferably greater than 90° C., very particularly preferably greater than 110° C.

In a preferred embodiment of the invention, the photoluminescence maximum of phosphorescent compound A is at least 20 nm shorter in wavelength than that of phosphorescent compound B, particularly preferably at least 30 nm shorter in wavelength. This applies, in particular, if compound A is a green-phosphorescent compound and compound B is a red-phosphorescent compound or if compound A is a blue-phosphorescent compound and compound B is a green-phosphorescent compound. If compound A is a dark-blue-phosphorescent compound and compound B is a pale-blue-phosphorescent compound, it is preferred for compound A to emit at least 10 nm shorter in wavelength than compound B. The photoluminescence maximum here is determined by measurement of the photoluminescence spectrum of a layer having a thickness of 50 nm in which compound A has been doped into the corresponding matrix material of the formula (1) in a proportion of 5% by vol. or compound B has been doped into the corresponding matrix material of the formula (1) in a proportion of 5% by vol.

The emission spectrum of the electroluminescent device predominantly corresponds as a whole to the emission spectrum of the compound emitting at longer wavelength, i.e. compound B.

In an embodiment of the invention, phosphorescent compound A is a green-luminescent compound and phosphorescent compound B is a red-luminescent compound.

In a further embodiment of the invention, phosphorescent compound A is a blue-luminescent compound and phosphorescent compound B is a green-luminescent compound or a red-luminescent compound.

In still a further embodiment of the invention, phosphorescent compound A is a dark-blue-luminescent compound or a compound which emits in the UV region and compound B is a pale-blue-luminescent compound.

Red luminescence here is taken to mean luminescence having a maximum of the photoluminescence spectrum in the range from 560 to 750 nm. Green luminescence is taken to mean luminescence having a maximum of the photoluminescence spectrum in the range from 490 to 560 nm. Blue luminescence is taken to mean luminescence having a maximum of the photoluminescence spectrum in the range from 440 to 490 nm. Dark-blue luminescence is taken to mean luminescence having a maximum of the photoluminescence spectrum in the range from 350 to 460 nm. Pale-blue luminescence is taken to mean luminescence having a maximum of the photoluminescence spectrum in the range from 460 to 490 nm. The photoluminescence spectrum here is measured as described above.

The proportion of phosphorescent compound A in the layer is preferably 5 to 50% by vol., particularly preferably 10 to 25% by vol., very particularly preferably 12 to 20% by vol.

The proportion of phosphorescent compound B in the layer is preferably 1 to 20% by vol., particularly preferably 3 to 10% by vol., very particularly preferably 4 to 7% by vol.

in the organic electroluminescent device according to the invention, phosphorescent compound A is preferably a material which is capable of trans-porting holes. Since, in particular, the position of the HOMO (highest occupied molecular orbital) is responsible for the hole-transport properties of the material, compound A preferably has an HOMO of >−5.9 eV, particularly preferably >−5.7 eV and very particularly preferably >−5.5 eV. The HOMO can be determined by photoelectron spectroscopy by means of a model AC-2 photoelectron spectrometer from Riken Keiki Co. Ltd. (http://www.rikenkeiki.com/pages/AC2.htm).

Preferred embodiments of phosphorescent compounds A and B and of the compound of the formula (1) are described below.

Suitable phosphorescent compounds A and B are, in particular, compounds which emit light, preferably in the visible region, on suitable excitation and in addition contain at least one atom having an atomic number of greater than 20, preferably greater than 38 and less than 84, particularly preferably greater than 56 and less than 80. Preferred phosphorescence emitters A and B are compounds which contain copper, molybdenum, tungsten, rhenium, ruthenium, osmium, rhodium, iridium, palladium, platinum, silver, gold or europium, in particular compounds which contain iridium or platinum.

Particularly preferred organic electroluminescent devices comprise, as phosphorescent compound A and/or as phosphorescent compound B, at least one compound of the formulae (2) to (5):

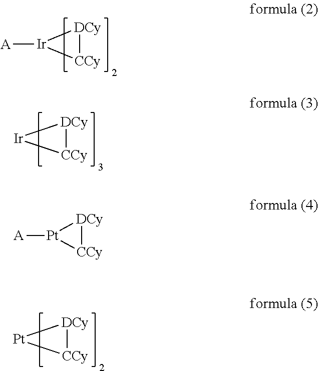

where R¹ has the same meaning as described above for formula (1), and the following applies to the other symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R¹;
A is, identically or differently on each occurrence, a monoanionic, bidentate-chelating ligand, preferably a diketonate ligand or a picolinate ligand.

A bridge may also be present between the groups DCy and CCy through the formation of ring systems between a plurality of radicals R¹. A bridge may furthermore also be present between two or three ligands CCy-DCy or between one or two ligands CCy-DCy and the ligand A through the formation of ring systems between a plurality of radicals R¹, giving a polydentate or polypodal ligand system.

Examples of the emitters described above are revealed by the applications WO 00/70655, WO 01/41512, WO 02/02714, WO 02/15645, EP 1191613, EP 1191612, EP 1191614, WO 04/081017, WO 05/033244, WO 05/042550, WO 05/113563, WO 06/008069, WO 06/061182, WO 06/081973 and the unpublished application DE 102008027005.9. In general, all phosphorescent complexes as are used in accordance with the prior art for phosphorescent OLEDs and as are known to the person skilled in the art in the area of organic electroluminescence are suitable, and the person skilled in the art will be able to use further phosphorescent compounds without inventive step. In particular, phosphorescent complexes with all emission colours are known to the person skilled in the art.

Compound A here is preferably a compound of the formula (3) given above, in particular tris(phenylpyridyl)iridium, which may be substituted by one or more radicals R¹. Compound A is very particularly preferably tris-(phenylpyridyl)iridium.

Compound B is preferably a compound of the formula (2), (3) or (5) given above, particularly preferably of the formula (2) or (5), very particularly preferably of the formula (2). A in formula (2) preferably stands for acetyl-acetonate or an acetylacetonate derivative.

Examples of preferred phosphorescent compounds A and B are shown in the following table.

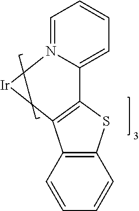

(1)

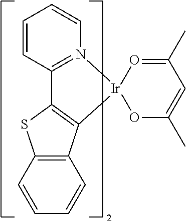

(2)

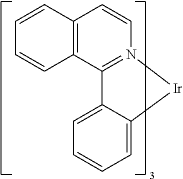

(3)

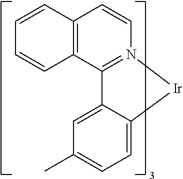

(4)

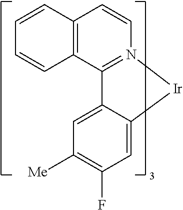

(5)

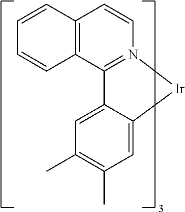

(6)

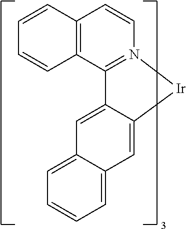

(7)

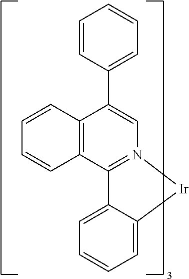

(8)

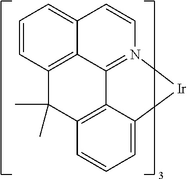

(9)

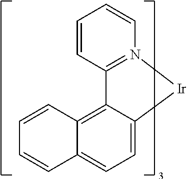

(10)

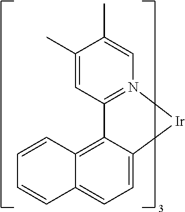

(11)

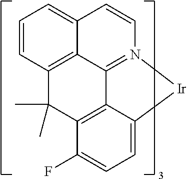

(12)

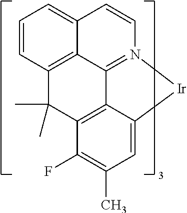

(13)

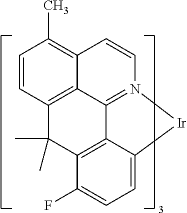

(14)

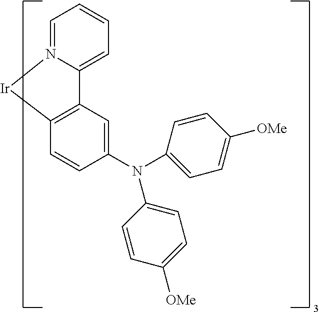

(15)

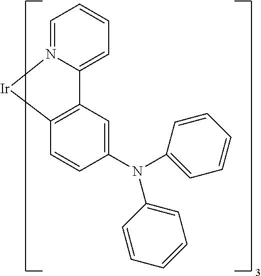

(16)

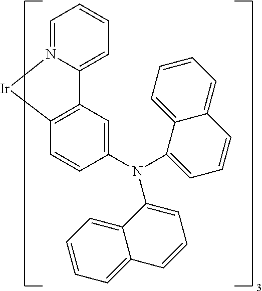

(17)

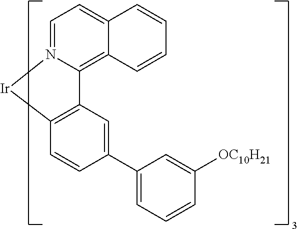

(18)

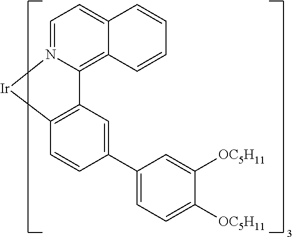

(19)

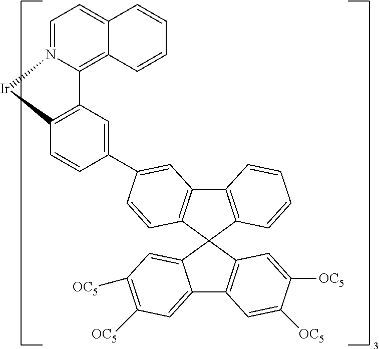

(20)

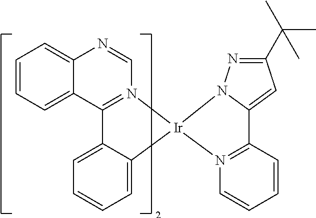

(21)

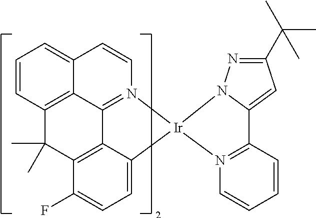

(22)

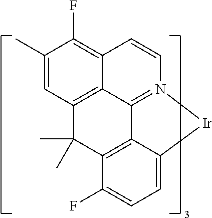

(23)

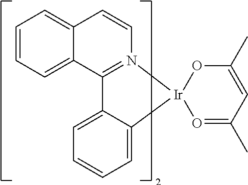

(24)

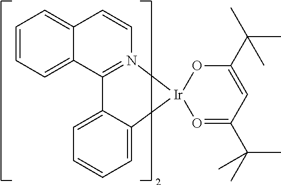

(25)

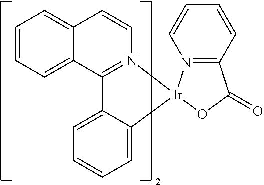

(26)

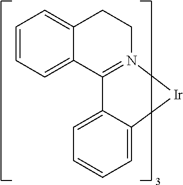

(27)

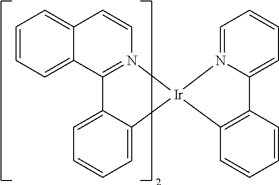

(28)

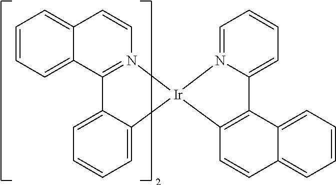

(29)

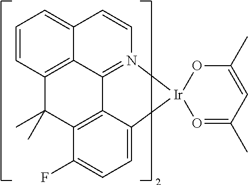

(30)

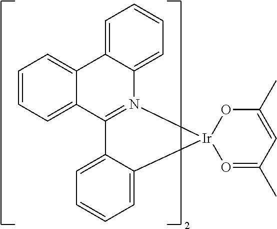

(31)

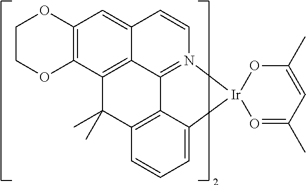

(32)

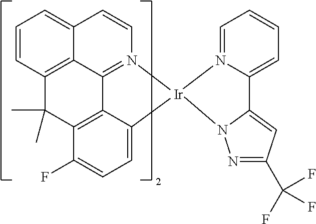

(33)

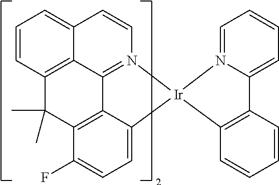

(34)

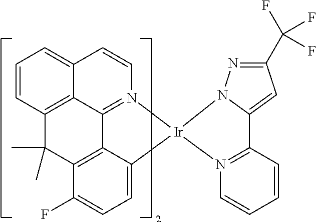

(35)

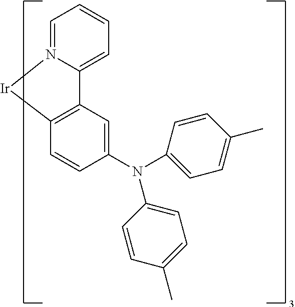

(36)

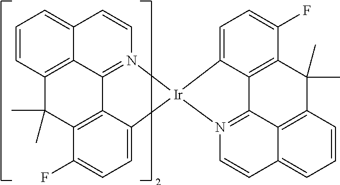

(37)

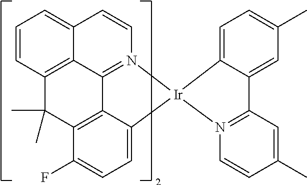

(38)

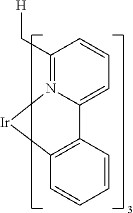

(39)

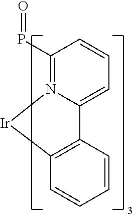

(40)

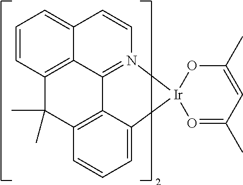

(41)

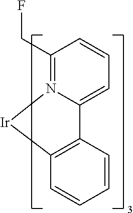

(42)

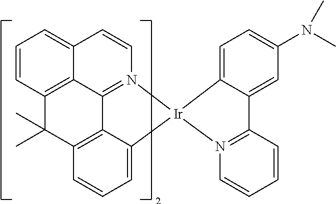

(43)

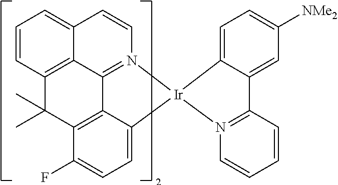

(44)

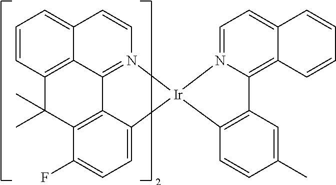

(45)

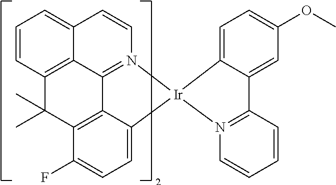

(46)

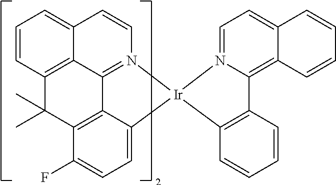

(47)

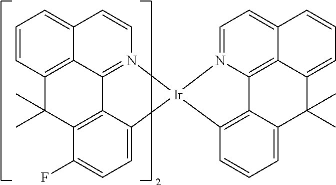

(48)

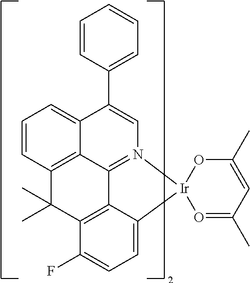

(49)

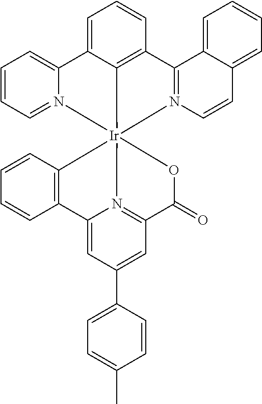

(50)

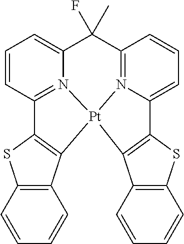

(51)

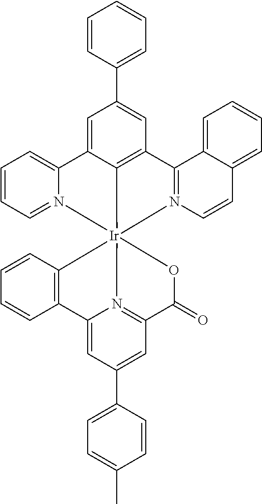

(52)

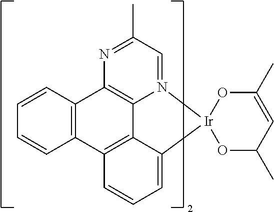

(53)

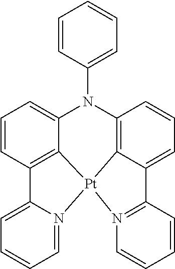

(54)

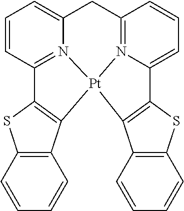

(55)

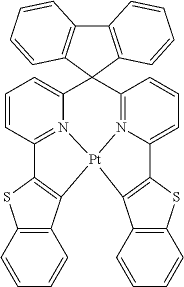

(56)

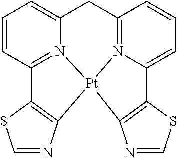

(57)

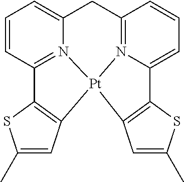

(58)

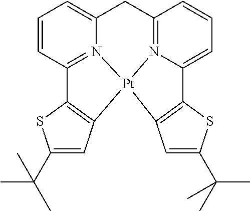

(59)

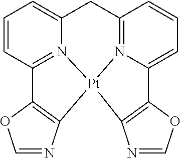

(69)

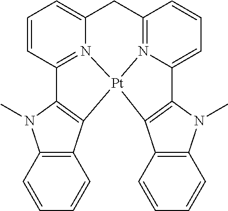

(61)

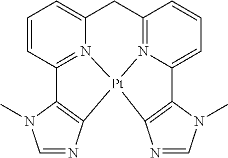

(62)

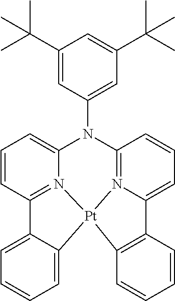

(63)

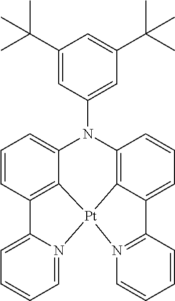

(64)

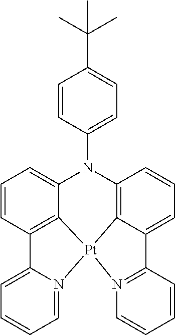

(65)

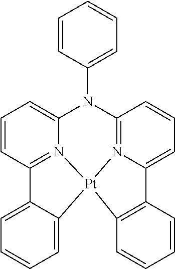

(66)

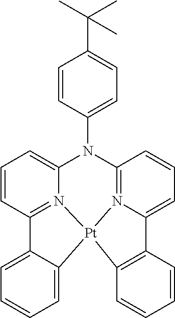

(67)

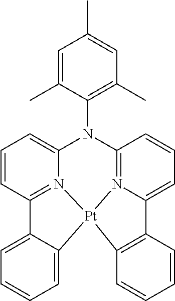

(68)

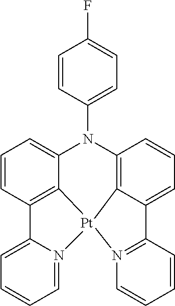

(69)

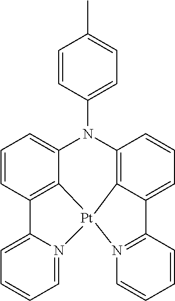

(70)

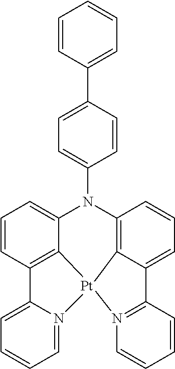

(71)

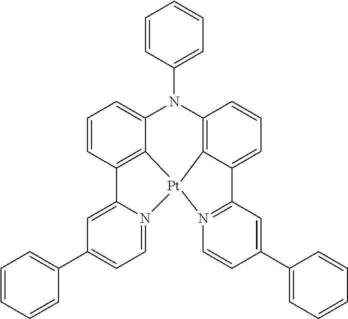

(72)

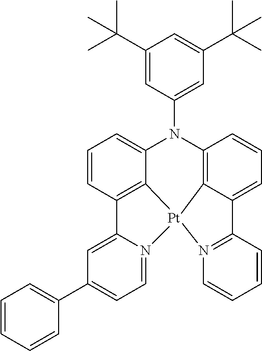

(73)

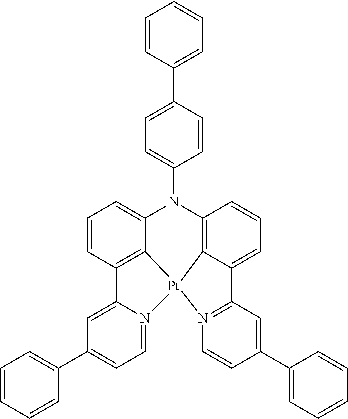

(74)

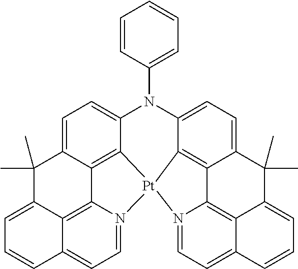

(75)

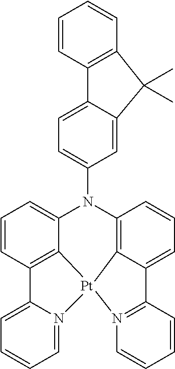

(76)

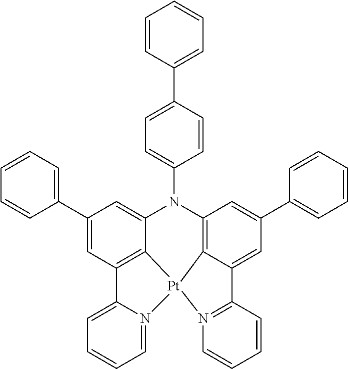

(77)

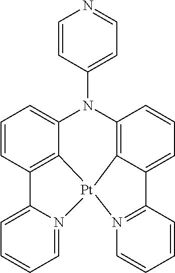

(78)

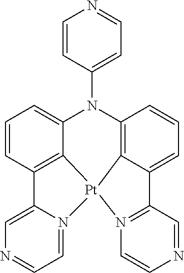

(79)

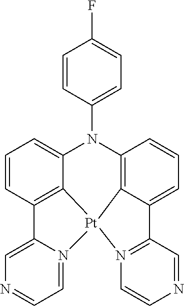

(80)

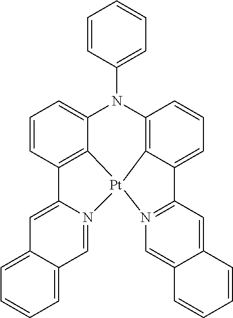

(81)

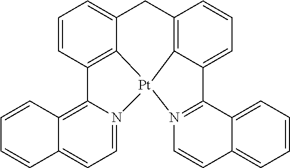

(82)

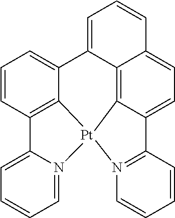

(83)

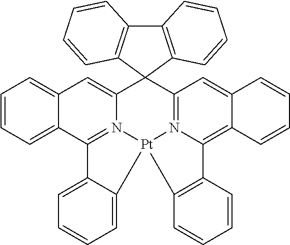

(84)

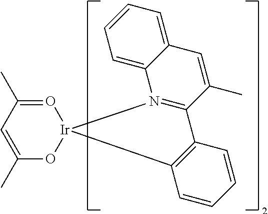

(85)

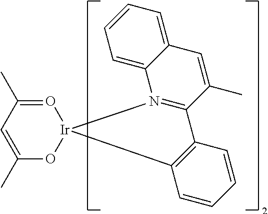

(86)

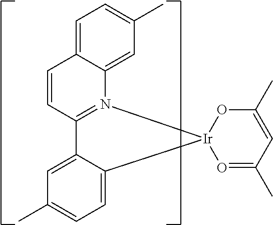

(87)

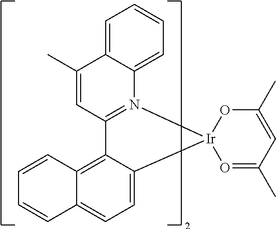

(88)

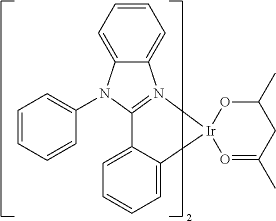

(89)

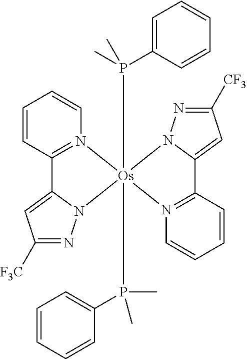

(90)

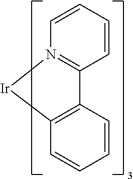

(91)

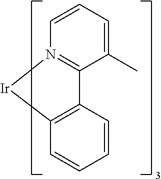

(92)

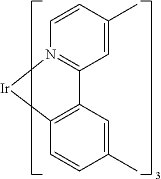

(93)

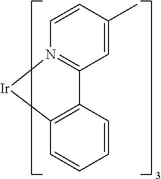

(94)

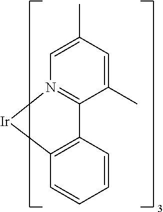

(95)

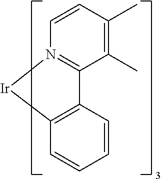

(96)

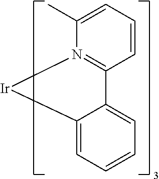

(97)

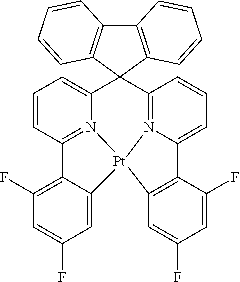

(98)

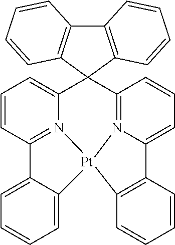

(99)

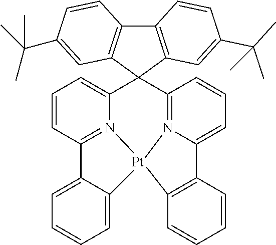

(100)

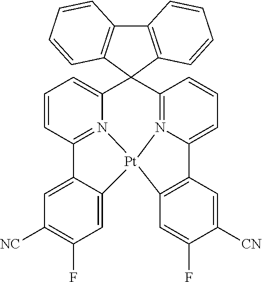

(101)

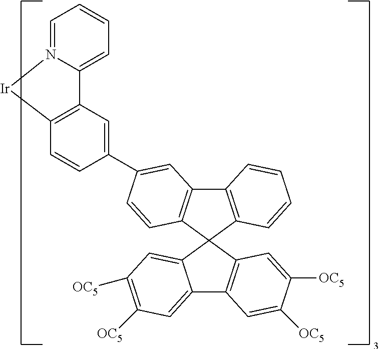

(102)

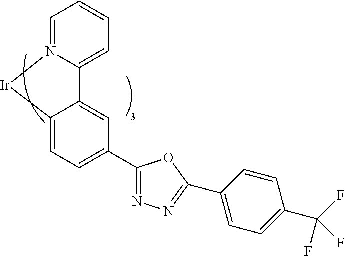

(103)

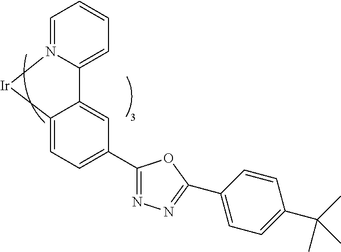

(104)

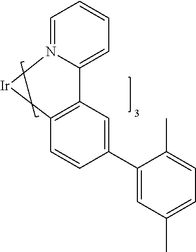

(105)

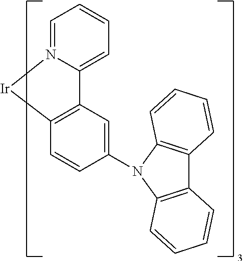

(106)

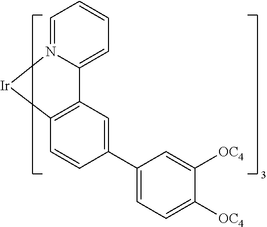

(107)

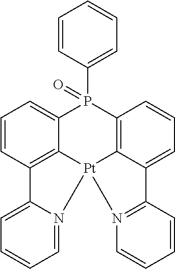

(108)

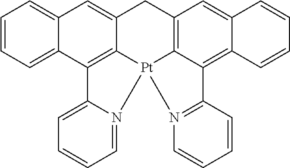

(109)

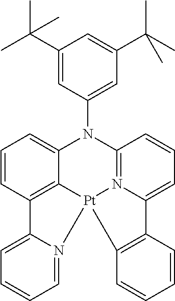

(110)

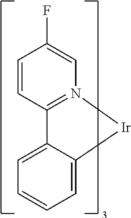

(111)

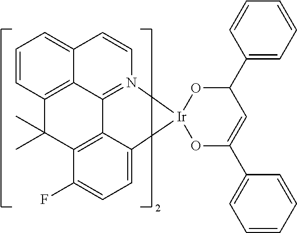

(112)

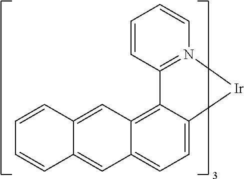

(113)

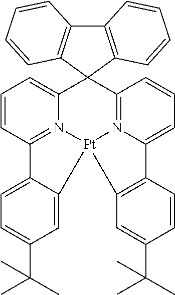

(114)

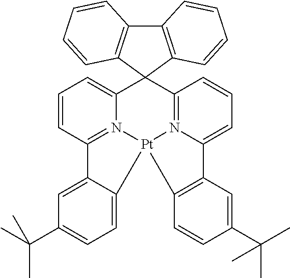

(115)

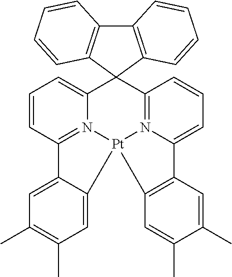

(116)

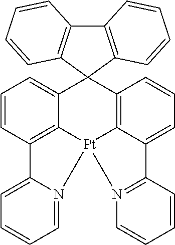

(117)

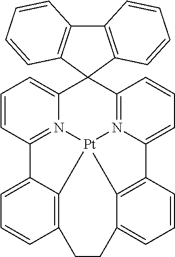

(118)

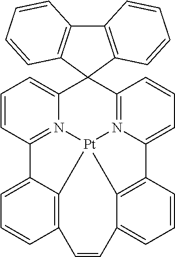

(119)

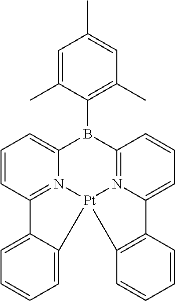

(120)

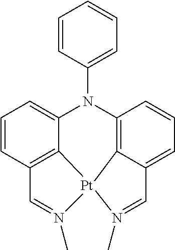

(121)

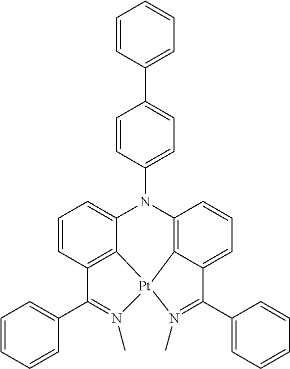

(122)

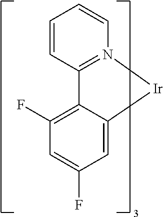

(123)

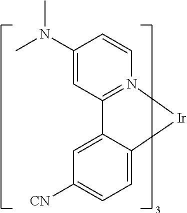

(124)

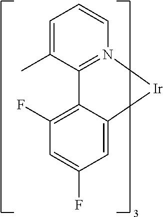

(125)

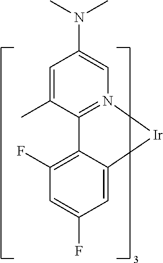

(126)

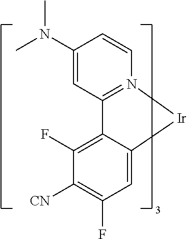

(127)

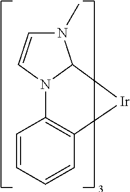

(128)

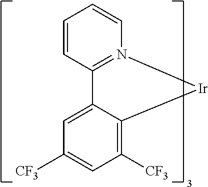

(129)

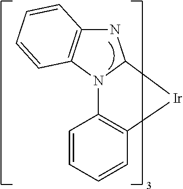

(130)

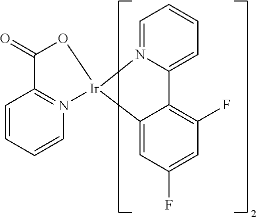

(131)

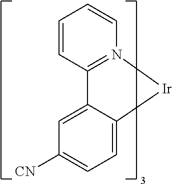

(132)

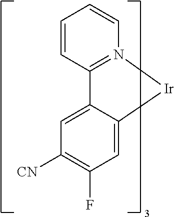

(133)

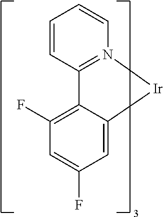

(134)

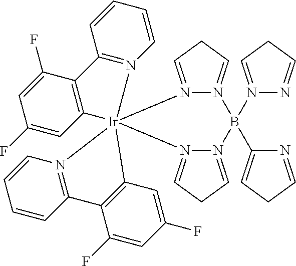

(135)

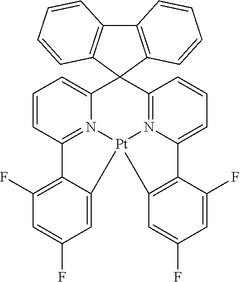

(136)

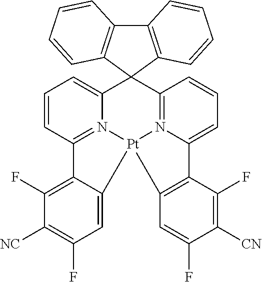

(137)

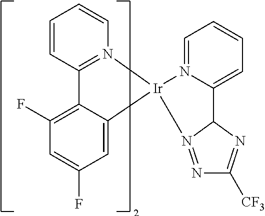

(138)

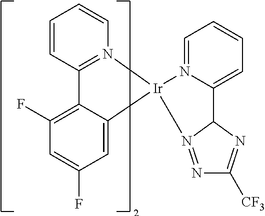

(139)

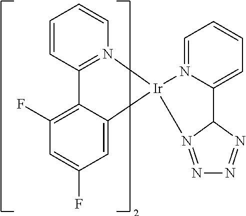

(140)

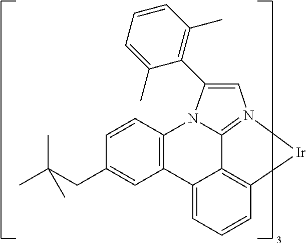

(141)

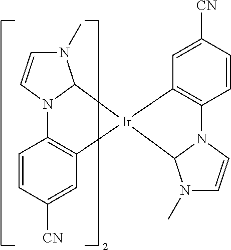

(142)

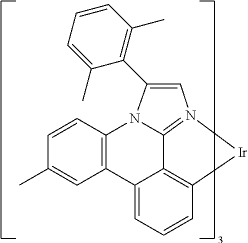

(143)

The matrix material used is, as described above, a compound of the formula (1).

Suitable compounds of the formula (1) are the ketones disclosed in WO 04/093207 and the unpublished DE 102008033943.1 and the phosphine oxides, sulfoxides and sulfones disclosed in WO 05/003253. These are incorporated into the present invention by way of reference.

In a preferred embodiment of the compounds of the formula (1), the symbol X stands for C or P, particularly preferably for C. They are thus preferably ketones or phosphine oxides, particularly preferably ketones.

It is evident from the definition of the compound of the formula (1) that this does not have to contain only one carbonyl or phosphine oxide group, but instead may also contain a plurality of these groups.

The group Ar in compounds of the formula (1) is preferably an aromatic ring system having 6 to 40 aromatic ring atoms. As defined above, the aromatic ring system does not necessarily have to contain only aromatic groups, but instead two aryl groups may also be interrupted by a non-aromatic group, for example by a further carbonyl group.

In a further preferred embodiment of the invention, the group Ar contains not more than two condensed rings. It is thus preferably built up only from phenyl and/or naphthyl groups, particularly preferably only from phenyl groups, but does not contain any larger condensed aromatic systems, such as, for example, anthracene.

Preferred groups Ar which are bonded to the carbonyl group are phenyl, 2-, 3- or 4-tolyl, 3- or 4-o-xylyl, 2- or 4-m-xylyl, 2-p-xylyl, o-, m- or p-tert-butylphenyl, o-, m- or p-fluorophenyl, benzophenone, 1-, 2- or 3-phenyl-methanone, 2-, 3- or 4-biphenyl, 2-, 3- or 4-o-terphenyl, 2-, 3- or 4-m-terphenyl, 2-, 3- or 4-p-terphenyl, 2′-p-terphenyl, 2′-, 4′- or 5′-m-terphenyl, 3′- or 4′-o-terphenyl, p,m-, o,p-, m,m-, o,m- or o,o-quaterphenyl, quinquephenyl, sexiphenyl, 1-, 2-, 3- or 4-fluorenyl, 2-, 3- or 4-spiro-9,9′-bifluorenyl, 1-, 2-, 3- or 4-(9,10-dihydro)phenanthrenyl, 1- or 2-naphthyl, 2-, 3-, 4-, 5-, 6-, 7- or 8-quinolinyl, 1-, 3-, 4-, 5-, 6-, 7- or 8-isoquinolinyl, 1- or 2-(4-methylnaphthyl), 1- or 2-(4-phenylnaphthyl), 1- or 2-(4-naphthyl-naphthyl), 1-, 2- or 3-(4-naphthylphenyl), 2-, 3- or 4-pyridyl, 2-, 4- or 5-pyrimidinyl, 2- or 3-pyrazinyl, 3- or 4-pyridazinyl, 2-(1,3,5-triazinyl), 2-, 3- or 4-(phenyl-pyridyl), 3-, 4-, 5- or 6-(2,2′-bipyridyl), 2-, 4-, 5- or 6-(3,3′-bipyridyl), 2- or 3-(4,4′-bipyridyl) and combinations of one or more of these radicals.

The groups Ar may be substituted by one or more radicals R¹. These radicals R¹ are preferably selected, identically or differently on each occurrence, from the group consisting of H, D, F, C(═O)Ar¹, P(═O)(Ar¹)₂, S(═O)Ar¹, S(═O)₂Ar¹, a straight-chain alkyl group having 1 to 4 C atoms or a branched or cyclic alkyl group having 3 to 5 C atoms, each of which may be substituted by one or more radicals R², where one or more H atoms may be replaced by F, or an aromatic ring system having 6 to 24 aromatic ring atoms, which may be substituted by one or more radicals R², or a combination of these systems; two or more adjacent substituents R¹ here may also form a mono- or polycyclic, aliphatic or aromatic ring system with one another. If the organic electroluminescent device is applied from solution, straight-chain, branched or cyclic alkyl groups having up to 10 C atoms are also preferred as substituents R¹. The radicals R¹ are particularly preferably selected, identically or differently on each occurrence, from the group consisting of H, D, C(═O)Ar¹ or an aromatic ring system having 6 to 24 aromatic ring atoms, which may be substituted by one or more radicals R², but is preferably unsubstituted.

In another preferred embodiment of the invention, the group Ar¹ is, identically or differently on each occurrence, an aromatic ring system having 6 to 24 aromatic ring atoms, which may be substituted by one or more radicals R². Ar¹ is particularly preferably, identically or differently on each occurrence, an aromatic ring system having 6 to 12 aromatic ring atoms.

Preferred aromatic ketones, phosphine oxides, sulfoxides and sulfones are therefore the compounds of the following formulae (6) to (30):

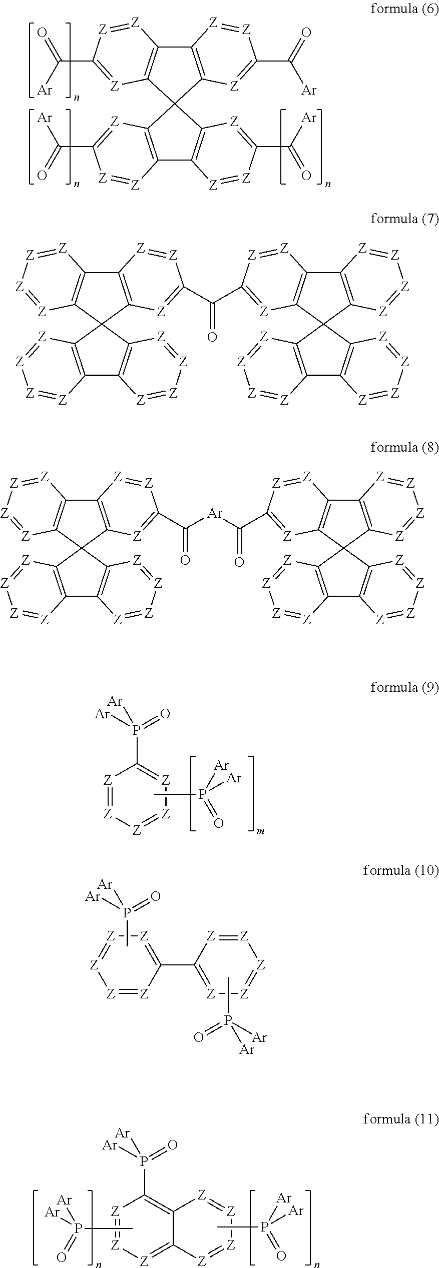

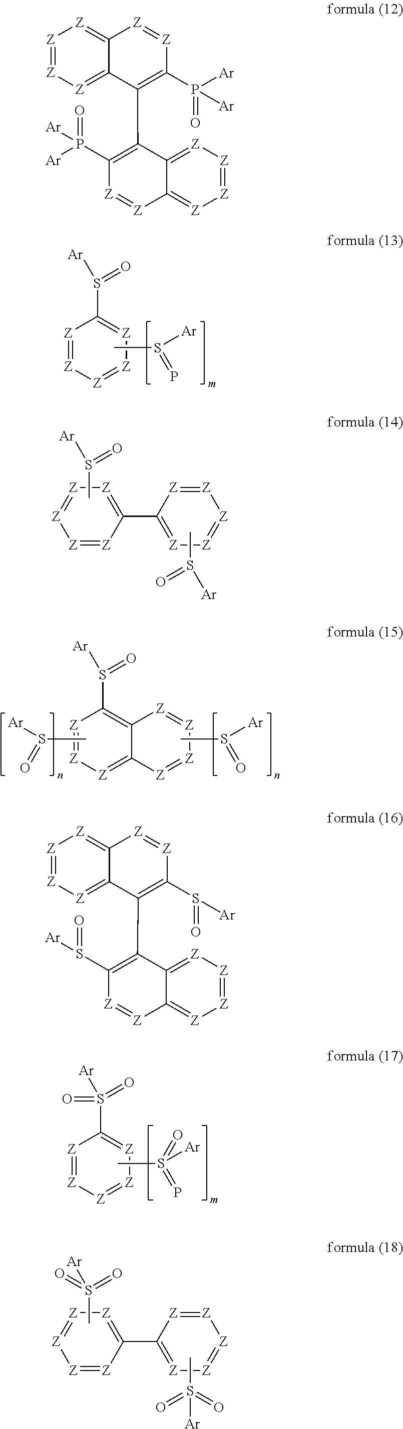

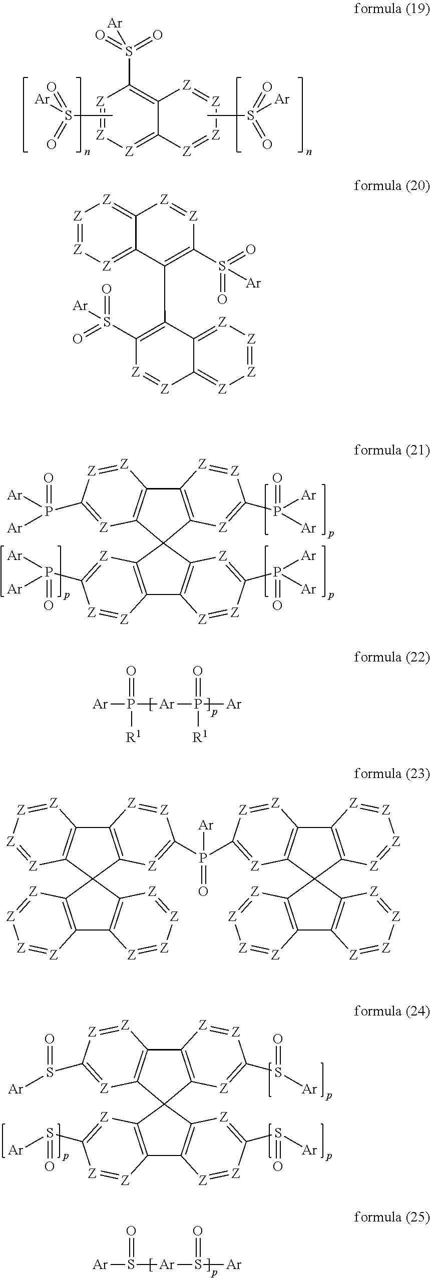

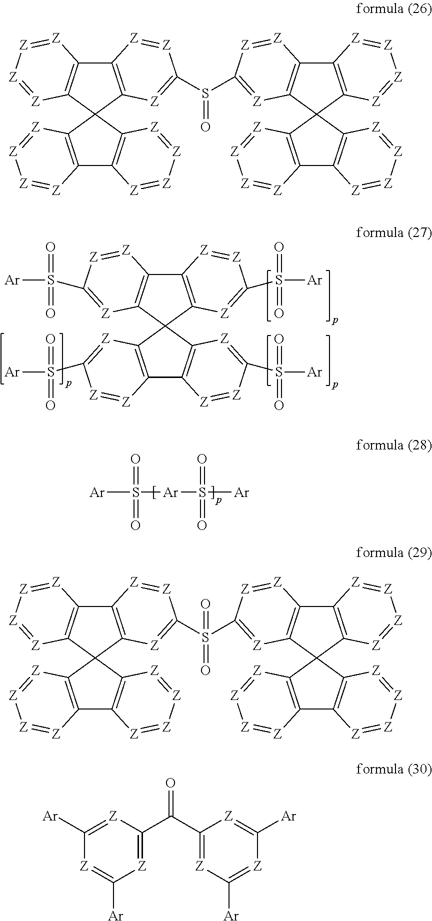

where Ar has the same meaning as described above, and furthermore:
Z is, identically or differently on each occurrence, CR¹ or N, where a maximum of 3 symbols Z per ring stand for N; Z is preferably equal to CR¹;
m is 1, 2, 3, 4 or 5;
n is, identically or differently on each occurrence, 0, 1, 2, 3 or 4;
p is on each occurrence, identically or differently, 0 or 1.

Ar in the formulae (6) to (30) given above preferably stands for an aromatic or heteroaromatic ring system having 5 to 30 aromatic ring atoms, which may be substituted by one or more radicals R. The groups Ar mentioned above are particularly preferred.

Particularly preferred aromatic ketones are benzophenone derivatives which are in each case substituted in the 3,3′,5,5′-positions by an aromatic or heteroaromatic ring system having 5 to 30 aromatic ring atoms, which may in turn be substituted by one or more radicals R¹ as defined above. Particular preference is furthermore given to spirobifluorene which is substituted by at least one C═O—Ar group, in particular in the 2-position. Particular preference is furthermore given to spirobifluorene which is substituted by at least one P═O(Ar)₂ group, in particular in the 2-position.

Examples of suitable compounds of the formula (1) are compounds (1) to (72) depicted below.

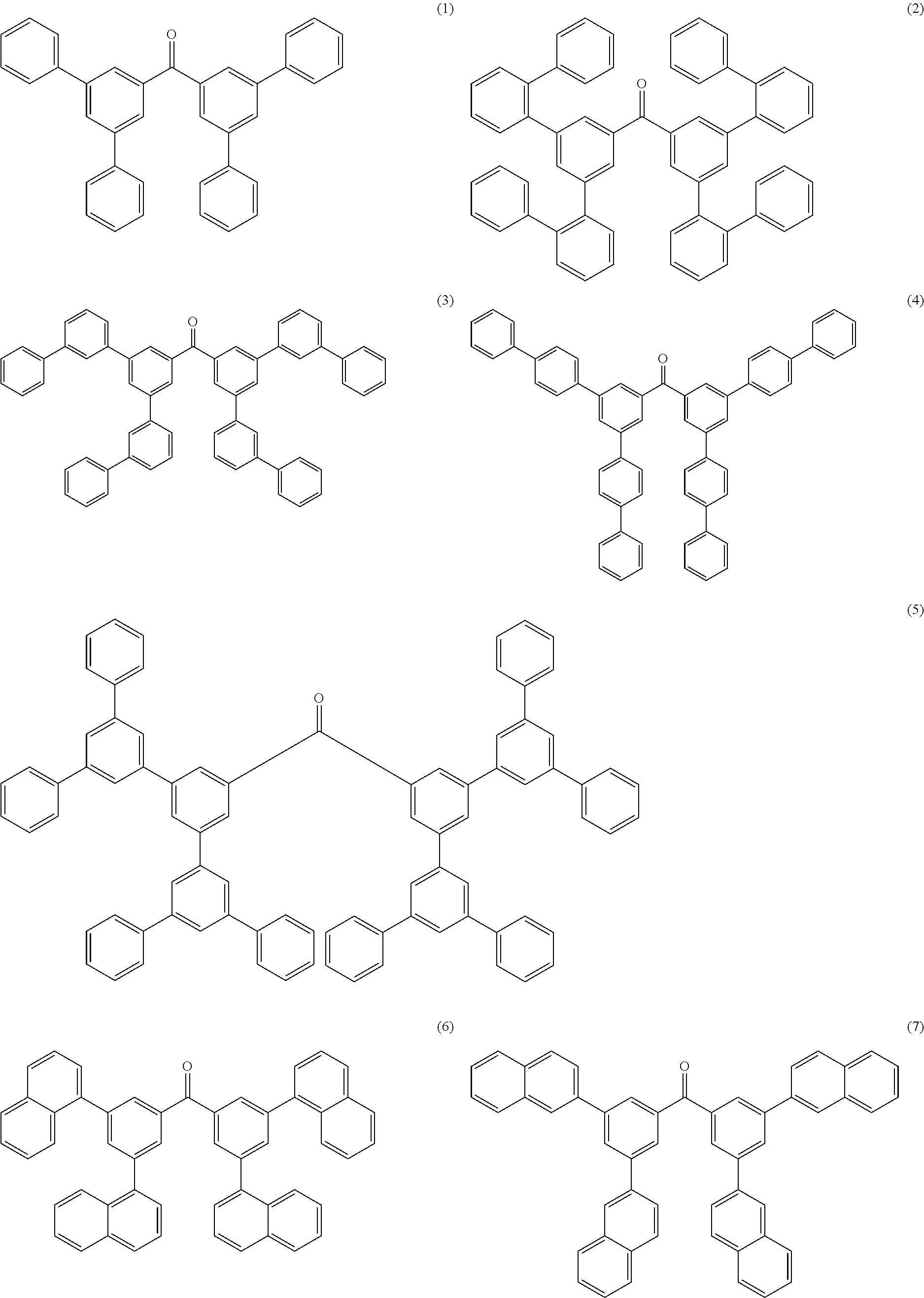

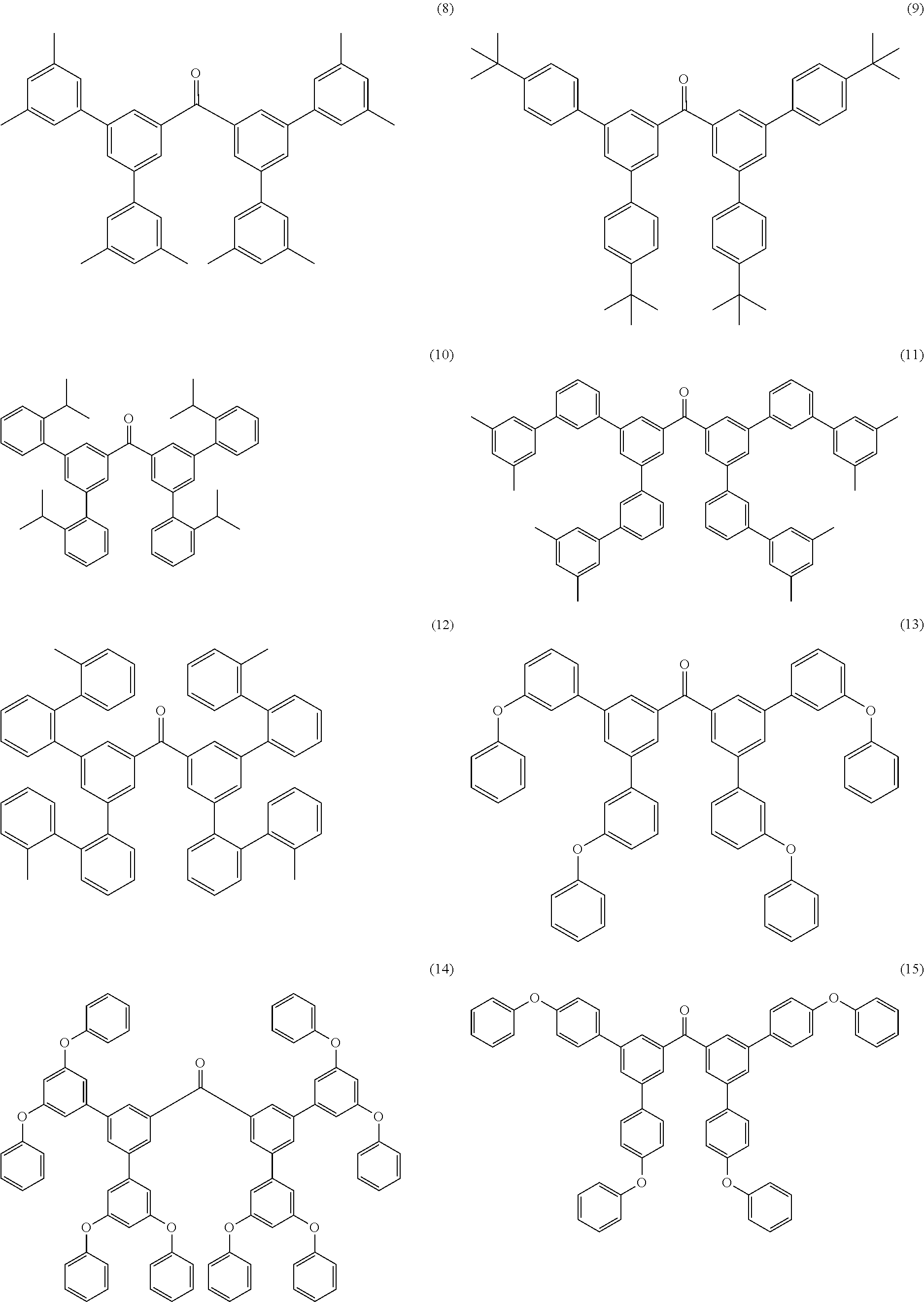

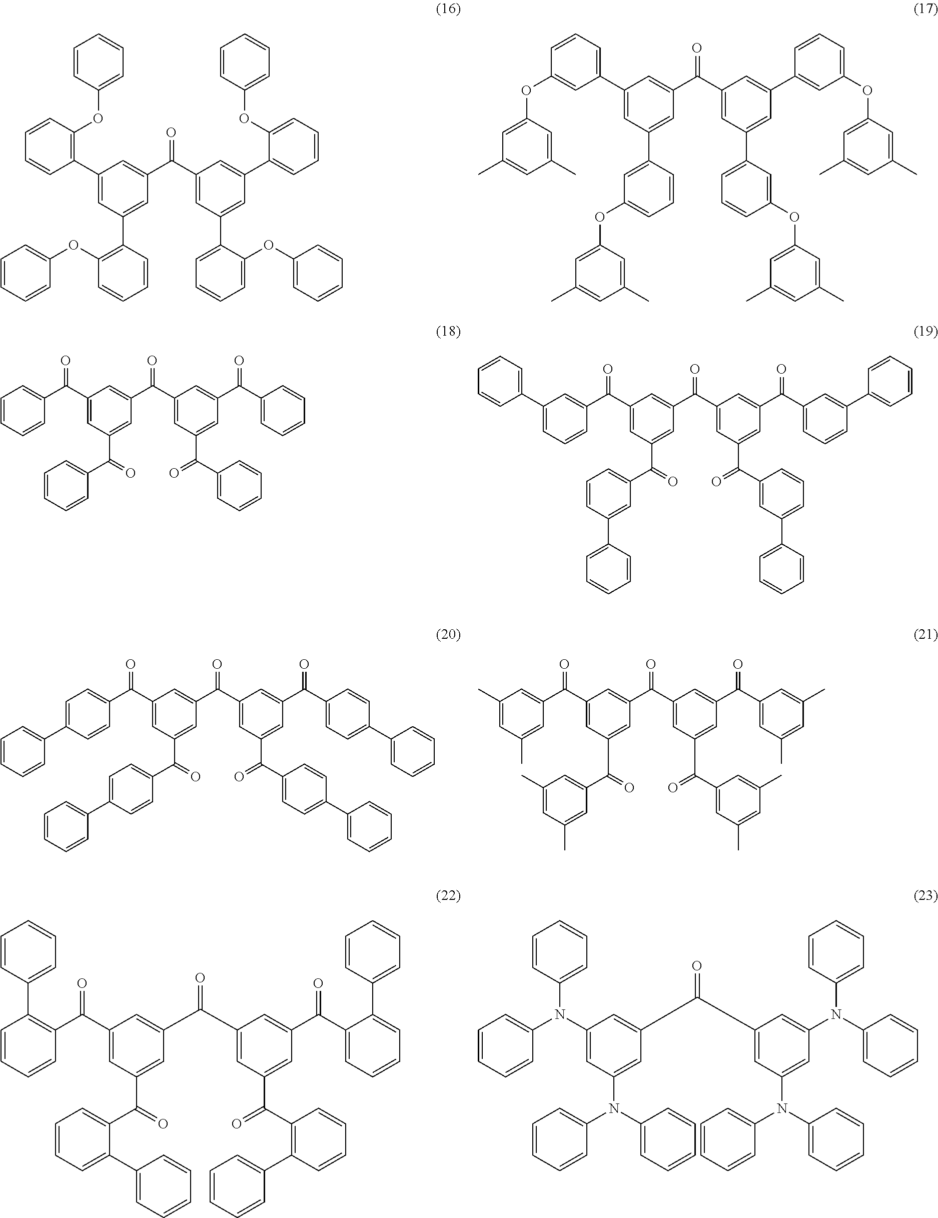

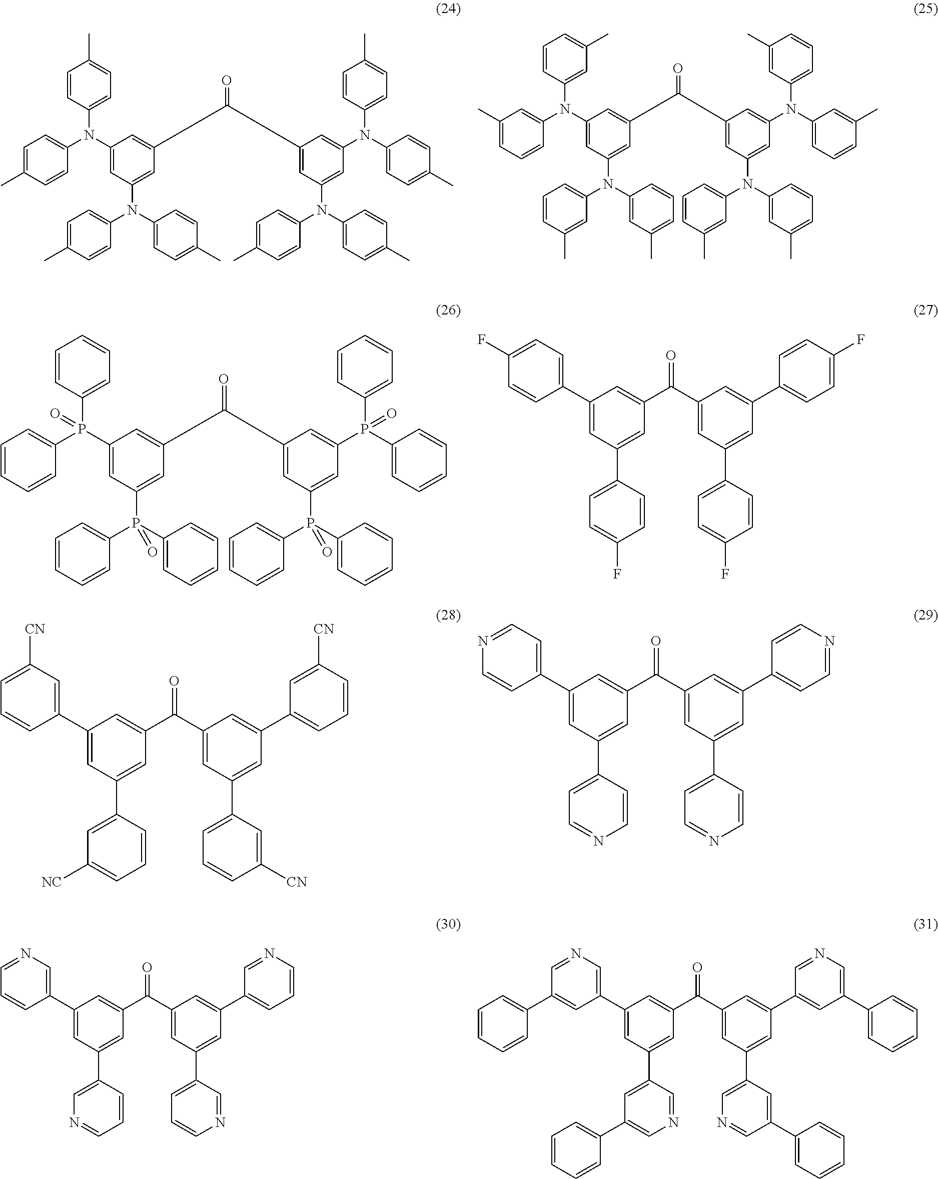

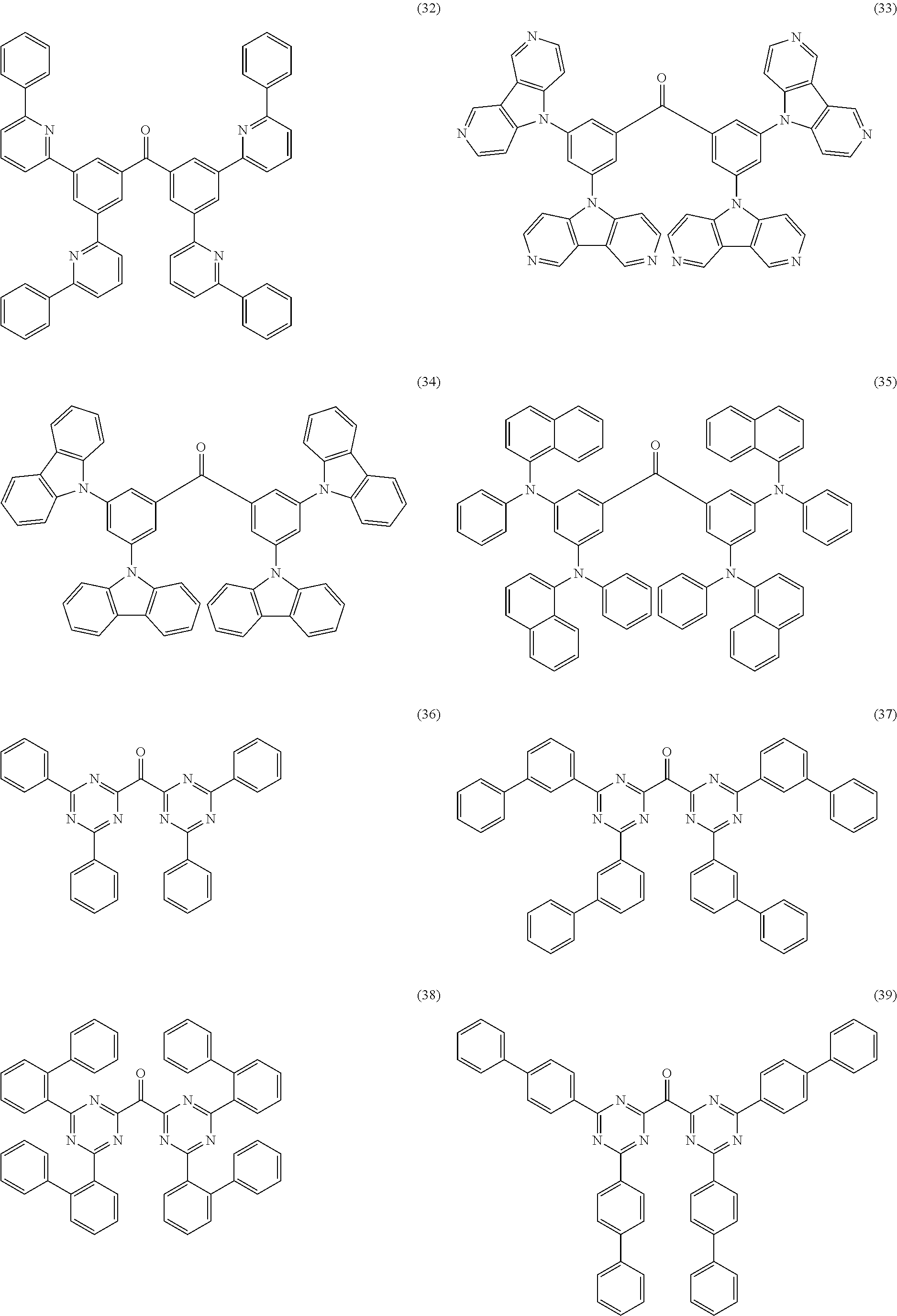

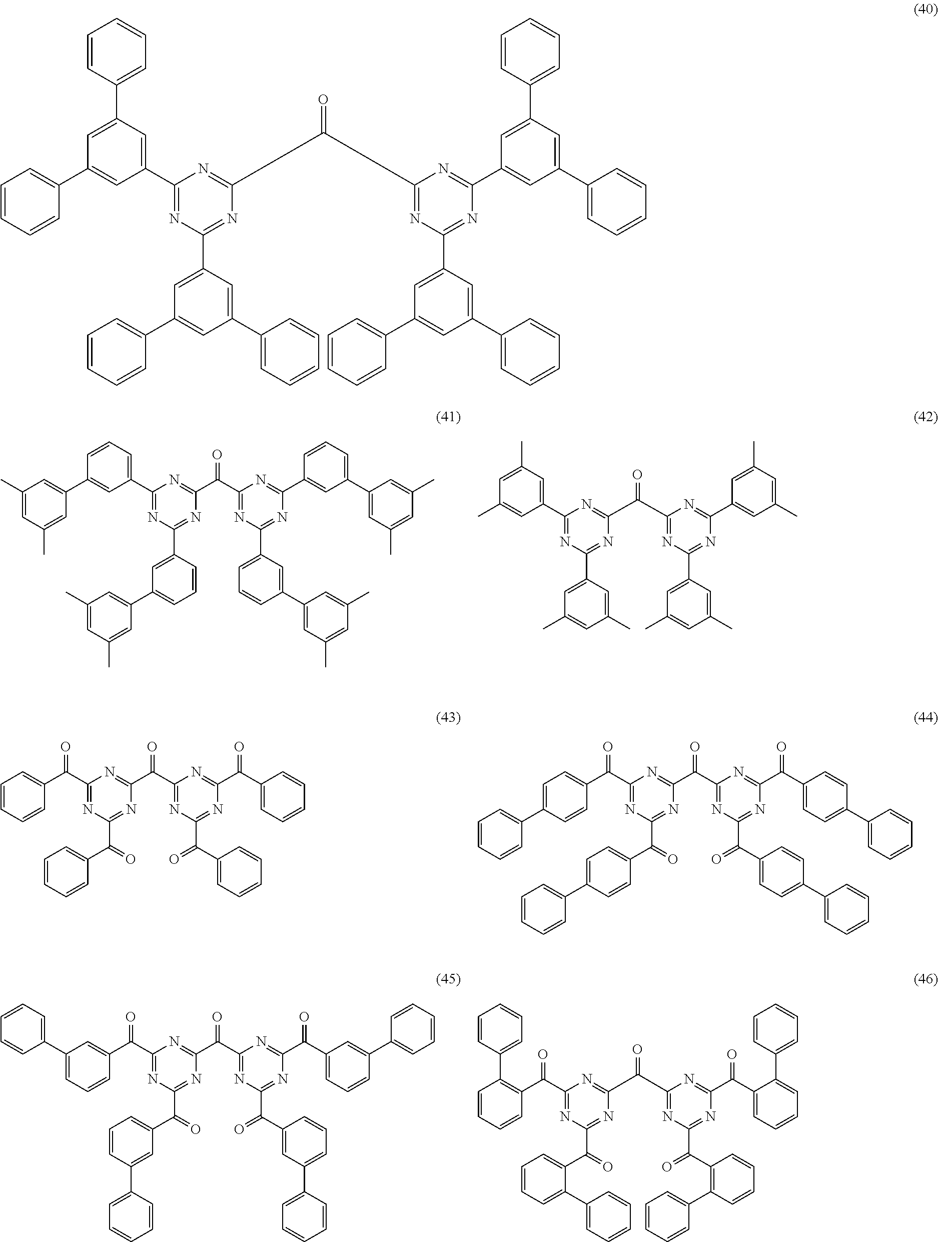

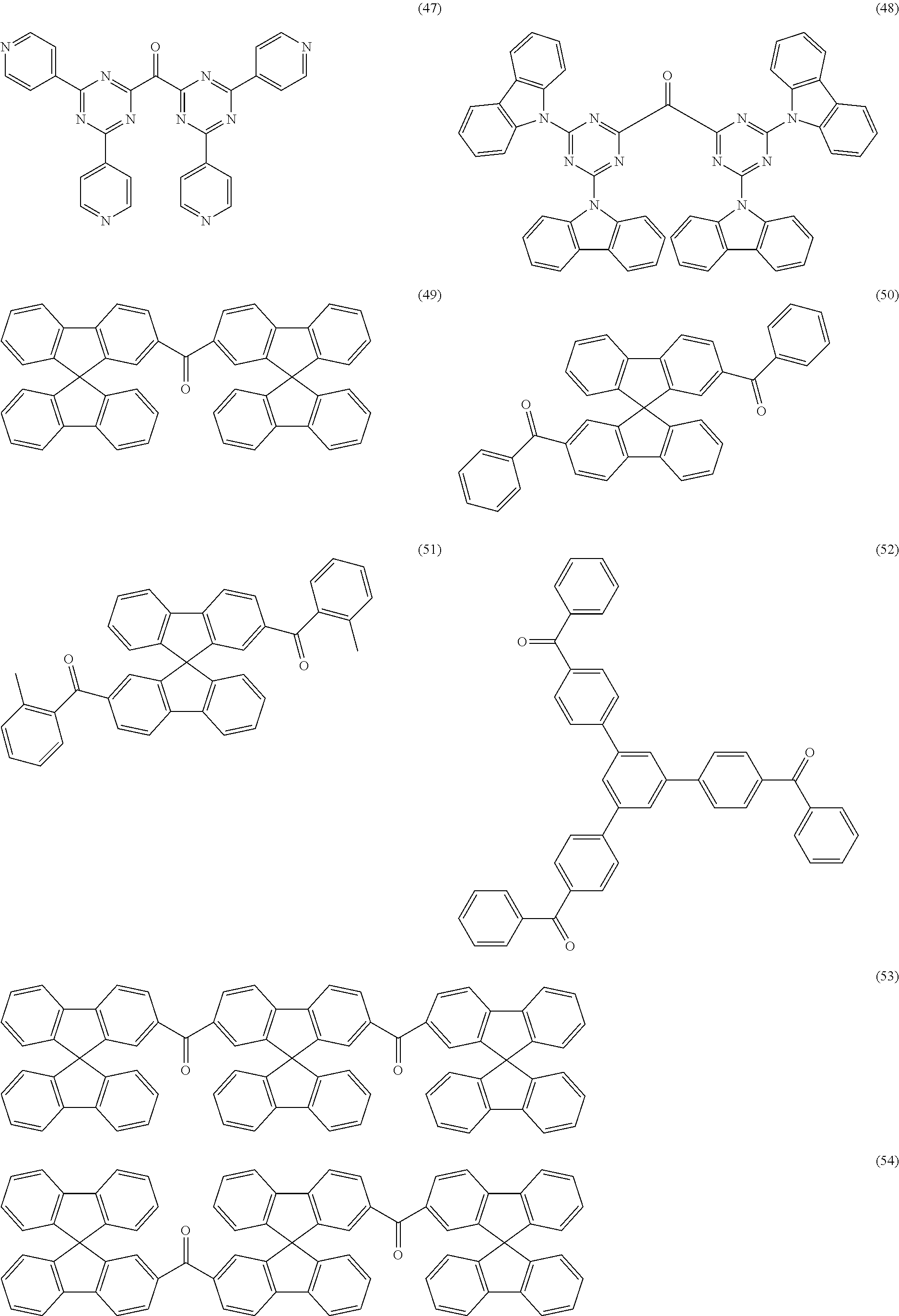

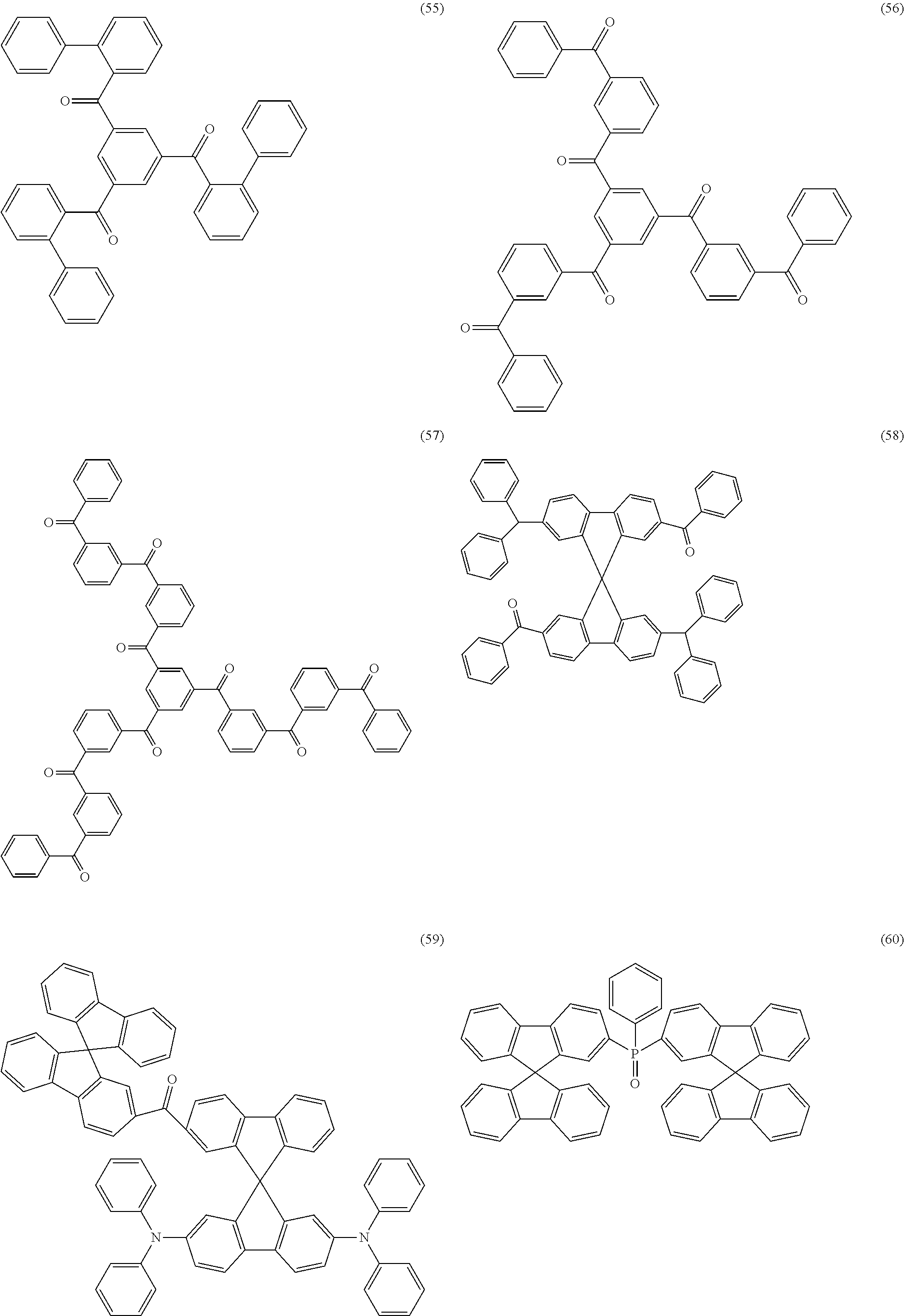

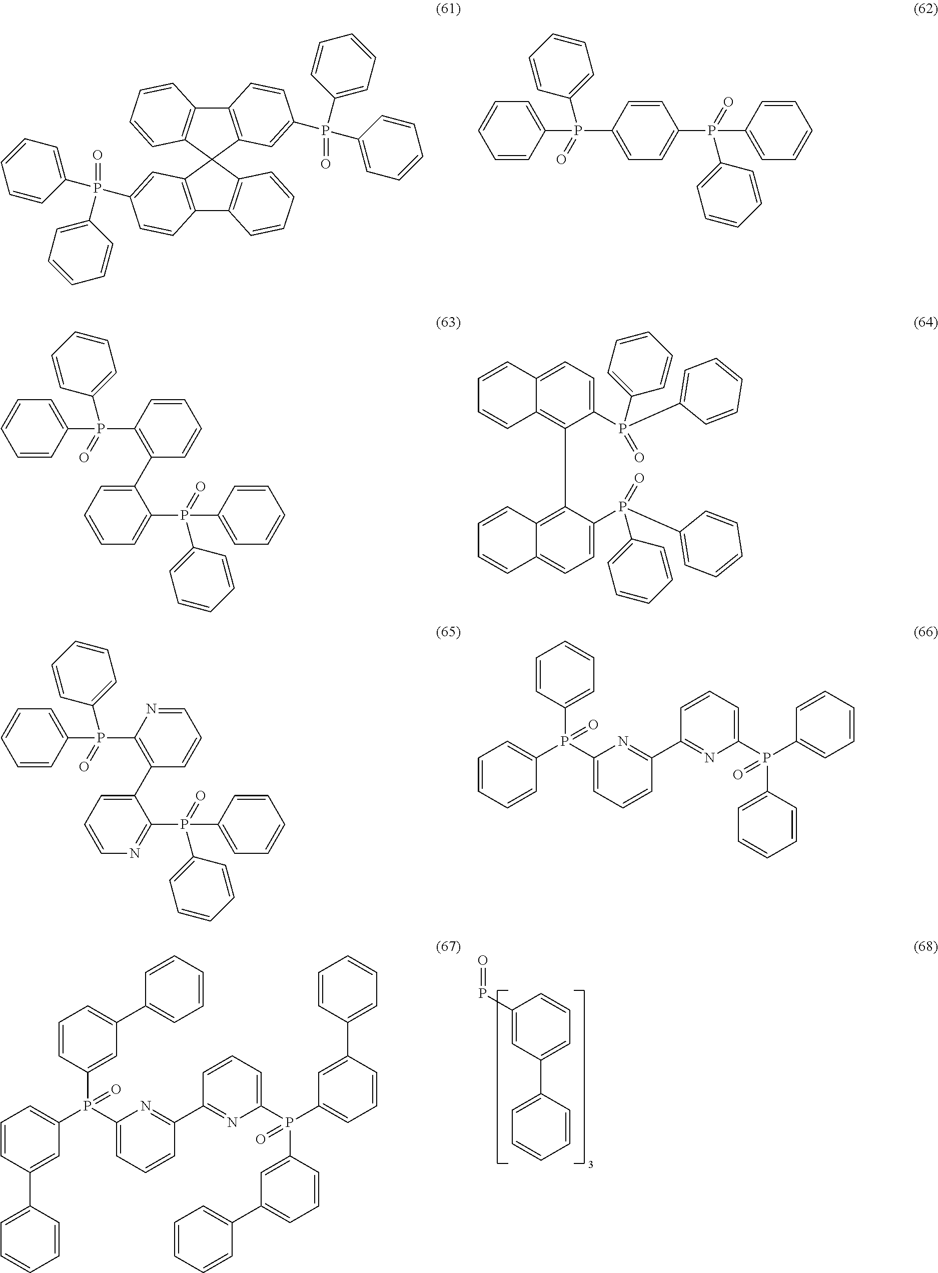

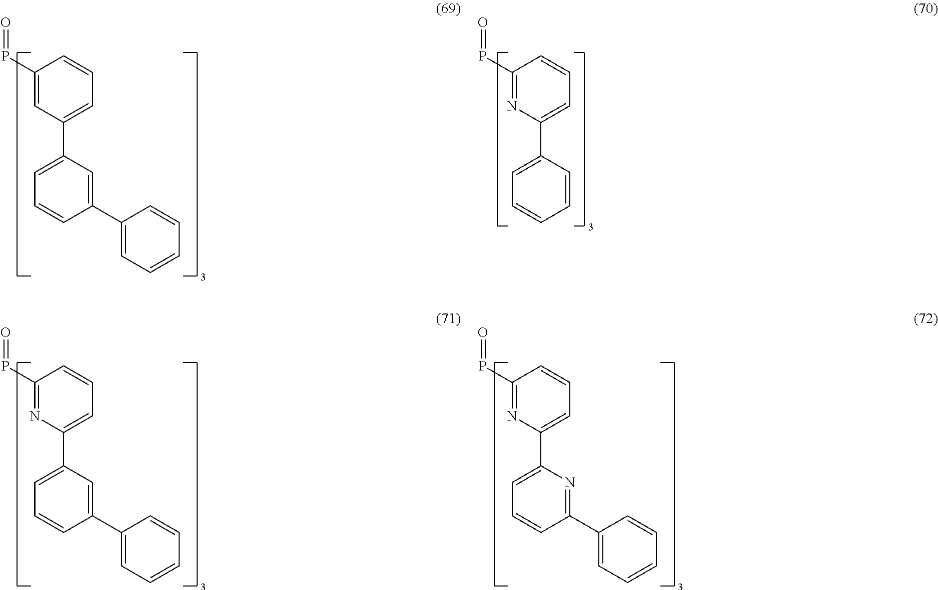

Apart from the cathode, anode and one or more emitting layers, the organic electroluminescent device may also comprise further layers. These are selected, for example, from in each case one or more hole-injection layers, hole-transport layers, hole-blocking layers, electron-transport layers, electron-injection layers, electron-blocking layers, exciton-blocking layers, charge-generation layers (IDMC 2003, Taiwan; Session 21 OLED (5), T. Matsumoto, T. Nakada, J. Endo, K. Mori, N. Kawamura, A. Yokoi, J. Kido, Multiphoton Organic EL Device Having Charge Generation Layer) and/or organic or inorganic p/n junctions. In addition, interlayers may be present, which control, for example, the charge balance in the device. Furthermore, the layers, in particular the charge-transport layers, may also be doped. The doping of the layers may be advantageous for improved charge transport. However, it should be pointed out that each of these layers does not necessarily have to be present, and the choice of the layers is always dependent on the compounds used.

In an embodiment of the invention, the organic electroluminescent device comprises a plurality of emitting layers, where at least one emitting layer comprises at least one phosphorescent compound A, a phosphorescent compound B and a compound of the formula (1). These emission layers particularly preferably have in total a plurality of emission maxima between 380 nm and 750 nm, resulting overall in white emission, i.e. various emitting compounds which are able to fluoresce or phosphoresce and which emit blue and yellow, orange or red light are used in the emitting layers. Particular preference is given to three-layer systems, i.e. systems having three emitting layers, where at least one of these layers comprises at least one phosphorescent compound A, a phosphorescent compound B and a compound of the formula (1) and where the three layers exhibit blue, green and orange or red emission (for the basic structure see, for example, WO 05/011013). The use of more than three emitting layers may also be preferred.

Preference is furthermore also given to the use of a plurality of matrix materials as a mixture, where one matrix material is selected from compounds of the formula (1). The compounds of the formula (1) have predominantly electron-transporting properties through the presence of the X═O group. If a mixture of two or more matrix materials is used, a further component of the mixture is therefore preferably a hole-transporting compound. Preferred hole-conducting matrix materials are triarylamines, carbazole derivatives, for example CBP(N,N-biscarbazolylbiphenyl) or the carbazole derivatives disclosed in WO 05/039246, US 2005/0069729, JP 2004/288381, EP 1205527 or WO 08/086,851, azacarbazoles, for example in accordance with EP 1617710, EP 1617711, EP 1731584, JP 2005/347160, bipolar matrix materials, for example in accordance with WO 07/137,725, and benzothiophene or dibenzothiophene derivatives, for example in accordance with WO 09/021,126. The mixture of the matrix materials may also comprise more than two matrix materials. It is furthermore also possible to use the matrix material of the formula (1) as a mixture with a further electron-transporting matrix material, for example with a second matrix material of the formula (1), with bipolar matrix materials, for example in accordance with WO 07/137,725, silanes, for example in accordance with WO 05/111172, azaboroles or boronic esters, for example in accordance with WO 06/117052. It is likewise possible to employ two or more materials of the formula (1).

Preference is furthermore given to an organic electroluminescent device, characterised in that one or more layers are applied by means of a sublimation process, in which the materials are vapour-deposited in vacuum sublimation units at a pressure of less than 10⁻⁶ mbar, preferably less than 10⁻⁶ mbar. However, it should be noted that the pressure may also be even lower, for example less than 10⁻⁷ mbar.

Preference is likewise given to an organic electroluminescent device, characterised in that one or more layers are applied by means of the OVPD (organic vapour phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing or offset printing, but particularly preferably LITI (light induced thermal imaging, thermal transfer printing) or ink-jet printing. Soluble compounds are necessary for this purpose. High solubility can be achieved through suitable substitution of the compounds. It is possible here not only for solutions of individual materials to be applied, but also solutions which comprise a plurality of compounds, for example matrix materials and dopants.

The organic electroluminescent device may also be produced as a hybrid system by applying one or more layers from solution and applying one or more other layers by vapour deposition. Thus, for example, it is possible to apply an emitting layer comprising a compound of the formula (1) and the phosphorescent compounds A and B from solution and to apply a hole-blocking layer and/or an electron-transport layer thereto by vacuum vapour deposition. The emitting layer comprising a compound of the formula (1) and the phosphorescent compounds A and B can likewise be applied by vacuum vapour deposition, and one or more other layers can be applied from solution.

These processes are generally known to the person skilled in the art and can be applied by him without inventive step to the organic electroluminescent devices according to the invention.

The present invention furthermore relates to mixtures comprising at least one phosphorescent compound A, at least one phosphorescent compound B and at least one aromatic ketone, aromatic phosphine oxide, aromatic sulfoxide or aromatic sulfone, preferably a compound of the formula (1).

The present invention still furthermore relates to solutions or formulations comprising at least one mixture according to the invention and at least one solvent.

The organic electroluminescent devices according to the invention have the following surprising advantages over the prior art:
1. The organic electroluminescent devices according to the invention have very high efficiency. This also applies, in particular, if phosphorescent metal complexes containing ketoketonate ligands, for example acetyl-acetonate ligands, are used.
2. The organic electroluminescent devices according to the invention simultaneously have a very good lifetime. This also applies, in particular, if phosphorescent metal complexes containing ketoketonate ligands are used.
3. The organic electroluminescent devices according to the invention simultaneously have a very low operating voltage. In particular, the operating voltage is significantly lower than with matrix materials based on carbazole derivatives.
4. The organic electroluminescent devices according to the invention have a very low roll-off behaviour. Thus, the roll-off is significantly less than with electroluminescent devices which also comprise a compound of the formula (1), but only one phosphorescent compound.

The invention is described in greater detail by the following examples without wishing to restrict it thereby. The person skilled in the art will be able, without taking an inventive step, to produce further organic electroluminescent devices according to the invention.

### EXAMPLES

### Examples 1-13

### Production and Characterisation of Organic Electro-Luminescent Devices in Accordance with the Invention

Electroluminescent devices according to the invention can be produced as described, for example, in WO 05/003253. The results for various OLEDs are compared below.

Examples 1-13 describe red-emitting OLEDs which are achieved through the following layer structure:
Hole-injection layer (HIL) 20 nm of 2,2′,7,7′-tetrakis(di-para-tolyl-amino)spiro-9,9′-bifluorene
Hole-transport layer (HTL) 20 nm of NPB (N-naphthyl-N-phenyl-4,4′-diaminobiphenyl)
Emission layer (EML) 30 nm of matrix material: spiro-ketone (SK) (bis(9,9′-spirobifluoren-2-yl) ketone) or CBP (4,4′-bis(carbazol-9-yl)biphenyl) Dopant: TER-1, TER-2 or TER-3 (see below); degree of doping see Table 1. Further dopant in examples according to the invention: Ir(ppy)₃ (fac-tris[2-phenyl-pyridyl]iridium)
Hole-blocking layer (HBL) 10 nm of SK
Electron conductor (ETL) 20 nm of AlQ₃ (tris(quinolinato)aluminium-(III))
Cathode 1 nm of LiF, 100 nm of Al on top.

The structures of TER-1, TER-2, TER-3, Ir(ppy)₃ and SK are depicted below for clarity:

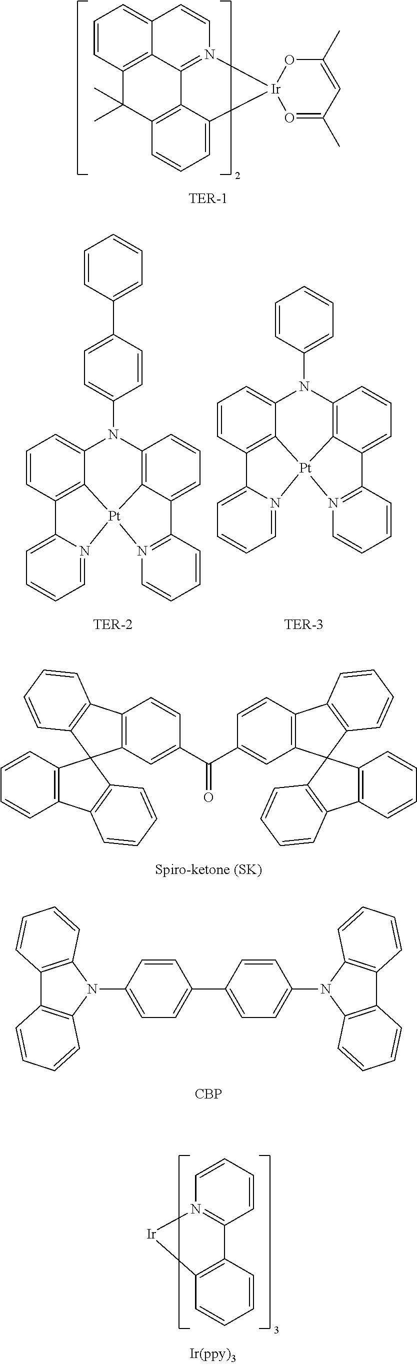

These as yet unoptimised OLEDs are characterised by standard methods; to this end, the electroluminescence spectra, the efficiency (measured in cd/A) as a function of the luminance, the operating voltage, calculated from current-voltage-luminous density characteristic lines (IUL characteristic lines), and the lifetime are determined.

Example 1 serves as comparative example and comprises TER-1 as dopant. Example 2 describes an OLED according to the invention which, besides TER-1, comprises Ir(ppy)₃ as further dopant. It can be seen from Table 1 that the OLED according to the invention has significantly improved efficiency and lifetime compared with the comparative example without the colour or operating voltage being impaired.

Analogously thereto, Comparative Examples 3-5 and Examples 6-9 according to the invention describe OLEDs comprising TER-2 as emitter and Comparative Example 10 and Example 11 according to the invention describe OLEDs comprising TER-3 as emitter. Here too, a considerable increase in the efficiency and in particular the operating lifetime is observed. In the case of TER-2, Example 7 according to the invention having an Ir(ppy)₃ concentration of 15% and a TER-2 concentration of 5% proves to have the longest lifetime. By contrast, it is evident in the comparative examples that an acceptable lifetime can only be achieved at an increased TER-2 concentration (15%, Comparative Example 3), but this results in significantly lower efficiency.

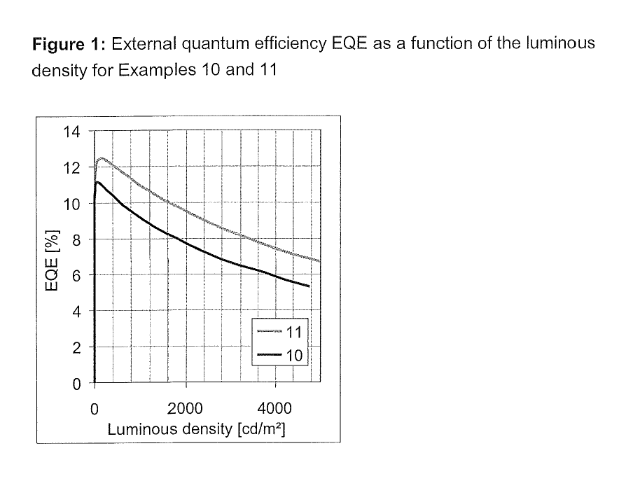

A further serious improvement in the OLEDs according to the invention is evident from a comparison of the efficiency-luminous density with reference to Examples 10 and 11 (FIG. 1). The decrease in efficiency (here in the form of the external quantum efficiency EQE) with increasing luminous density is significantly less in the case of the OLED according to the invention (Example 11) than in Comparative Example 10. Whereas, for example, the EQE drops from 12.2% to 8.3% (and thus by 27%) from 400 cd/m² to 4000 cd/m² in the case of the OLED according to the invention (Example 11), the drop in the comparative example (Example 10) is 45% from 10.4% to 5.7%.

Comparative Examples 12 and 13 show the effect of a second dopant on use of the host material CBP in accordance with the prior art. A slight improvement in the efficiency and lifetime also occurs here, but—besides the level of the values, which is significantly worse anyway—is much less pronounced in percentage terms than on use of the matrix materials encompassed by the invention in Examples 1-11. However, the operating voltage also increases somewhat in this case.

TABLE 1
Device results

| | | | | Efficiency | | | Lifetime 50% |
|---|---|---|---|---|---|---|---|
| | Matrix | Dopant 1 | Dopant 2 | [cd/A] at | Voltage [V] | | [h], initial luminance |
| Ex. | material | (conc.) | (conc.) | 1000 cd/m² | at 1000 cd/m² | CIE x/y | 1000 cd/m² |
| 1 (comp.) | SK | TER-1 (15%) | — | 19 | 4.0 | 0.62/0.38 | 3500 |
| 2 | SK | Ir(ppy)₃ (15%) | TER-1 (5%) | 29 | 4.0 | 0.62/0.38 | 8000 |
| 3 (comp.) | SK | TER-2 (15%) | — | 6 | 5.6 | 0.66/0.34 | 15000 |
| 4 (comp.) | SK | TER-2 (10%) | — | 8 | 5.3 | 0.66/0.34 | 10000 |
| 5 (comp.) | SK | TER-2 (5%) | — | 9 | 5.2 | 0.65/0.35 | 2500 |
| 6 | SK | Ir(ppy)₃ (10%) | TER-2 (5%) | 13 | 5.5 | 0.65/0.35 | 22000 |
| 7 | SK | Ir(ppy)₃ (15%) | TER-2 (5%) | 12 | 5.5 | 0.65/0.35 | 34000 |
| 8 | SK | Ir(ppy)₃ (15%) | TER-2 (10%) | 10 | 5.4 | 0.65/0.35 | 30000 |
| 9 | SK | Ir(ppy)₃ (25%) | TER-2 (5%) | 11 | 5.3 | 0.65/0.35 | 26000 |
| 10 (comp.) | SK | TER-3 (10%) | — | 10 | 5.3 | 0.66/0.33 | 3000 |
| 11 | SK | Ir(ppy)₃ (15%) | TER-3 (5%) | 13 | 5.3 | 0.66/0.34 | 10000 |
| 12 (comp.) | CBP | TER-1 (5%) | — | 23 | 4.6 | 0.62/0.38 | 1200 |
| 13 (comp.) | CBP | Ir(ppy)₃ (15%) | TER-1 (5%) | 27 | 4.9 | 0.62/0.38 | 1800 |

### Examples 14-16

### Production and Characterisation of Organic Electro-Luminescent Devices in Accordance with the Invention

Examples 14-16 describe blue- and green-emitting OLEDs which are achieved through the following layer structure and can be produced by the above-mentioned general process:
Hole-injection layer (HIL) 20 nm of 2,2′,7,7′-tetrakis(di-para-tolyl-amino)spiro-9,9′-bifluorene
Hole-transport layer (HTL) 5 nm of NPB (N-naphthyl-N-phenyl-4,4′-diaminobiphenyl)
Electron-blocking layer (EBL) 15 nm of EBM
Emission layer (EML) 40 nm of ketone (K) bis[1,3′;1′,1″;3″,1′″;3′″,1″″]-quinquephenyl-5″-ylmethanone in accordance with DE102008033943.1, Example 3, (vapour-deposited)
Dopant Ir(ppy)₃ (fac-tris[2-phenylpyridyl]iridium) as comparative example; in examples according to the invention, dopant 1 doped with dopant 2 (degree of doping see Table 2). Dopant 1 and dopant 2 are TEB, Flrpic or Ir(ppy)₃
Hole-blocking layer (HBL) 10 nm of ketone (K)
Electron conductor (ETL) 20 nm of AlQ₃ (tris(quinolinato)aluminium (III))
Cathode 1 nm of LiF, 100 nm of Al on top.

The structures of EBM, TEB, Flrpic and K are depicted below for clarity.

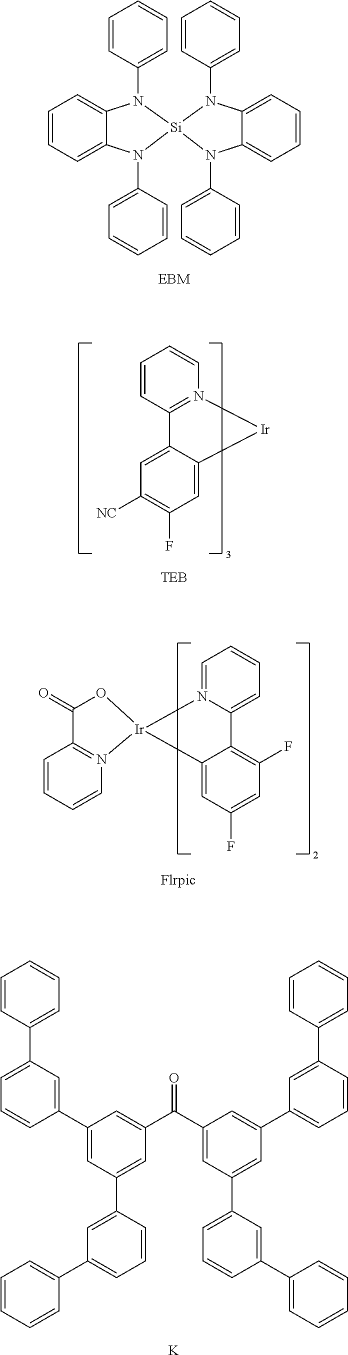

TABLE 2
Device results

| | Host | Dopant 1 + | Dopant 2 + | Efficiency [cd/A] | Voltage [V] at | |
|---|---|---|---|---|---|---|
| Ex. | material | concentration | concentration | at 1000 cd/m² | 1000 cd/m² | CIE x/y |
| 14 (comp.) | K | Irppy (10%) | — | 44 | 4.9 | 0.33/0.61 |
| 15 | K | Flrpic (10%) | Irppy (5%) | 58 | 5.4 | 0.32/0.62 |
| 16 | K | TEB (10%) | Flrpic (5%) | 27 | 7.0 | 0.16/0.34 |

As can be seen from the table, the efficiency is increased by the introduction of the dopant Flrpic in a green Ir(ppy)₃ device. The colour improves at the same time. This concept can also be implemented in a blue-green-emitting device of high efficiency, as shown by Example 16.

1.-15. (canceled)

16. An organic electroluminescent device comprising, in at least one emitting layer,
(A) a phosphorescent compound A,
(B) a phosphorescent compound B which is different from the phosphorescent compound A, and
(C) a matrix material selected from the group consisting of aromatic ketones, aromatic phosphine oxides, aromatic sulfoxides and aromatic sulfones.

17. The organic electroluminescent device according to claim 16, wherein the aromatic ketone, the aromatic phosphine oxide, the aromatic sulfone or the aromatic sulfoxide is selected from compounds of the formula (1) 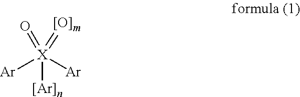
where the following applies to the symbols and indices used:
X is C, P or S;
Ar is on each occurrence, identically or differently, an aromatic or heteroaromatic ring system having 5 to 80 aromatic ring atoms, which optionally in each case is substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkenyl, alkynyl, alkoxy or thioalkoxy group having 1 to 40 C atoms or a branched or cyclic alkyl, alkenyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which optionally in each case is substituted by one or more radicals R², or an aryloxy or heteroaryloxy group having 5 to 60 aromatic ring atoms, which is optionally substituted by one or more radicals R², or an aralkyl or heteroaralkyl group having 5 to 60 aromatic ring atoms, which is optionally substituted by one or more radicals R², or a combination of these systems; two or more adjacent substituents R¹ optionally forms a mono- or polycyclic, aliphatic or aromatic ring system with one another;
Ar¹ is on each occurrence, identically or differently, an aromatic or heteroaromatic ring system having 5 to 40 aromatic ring atoms, which is optionally substituted by one or more radicals R²;
R² is on each occurrence, identically or differently, H, D or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic or aromatic ring system with one another;
n is 0 for X═C or S and is 1 for X═P;
m is 0 for X═C or P and is 0 or 1 for X═S.

18. The organic electroluminescent device according to claim 16, wherein the photoluminescence maximum of phosphorescent compound A is at least 20 nm shorter in wavelength than that of phosphorescent compound B.

19. The organic electroluminescent device according to claim 16, wherein the photoluminescence maximum of phosphorescent compound A is at least 30 nm shorter in wavelength than that of phosphorescent compound B.

20. The organic electroluminescent device according to claim 16, wherein the phosphorescent compound A is a green-luminescent compound and phosphorescent compound B is a red-luminescent compound or in that phosphorescent compound A is a blue-luminescent compound and phosphorescent compound B is a green-luminescent compound or a red-luminescent compound or in that phosphorescent compound A is a dark-blue-luminescent compound or a compound which emits in the UV region and compound B is a pale-blue-luminescent compound.

21. The organic electroluminescent device according to claim 16, wherein the proportion of phosphorescent compound A in the layer is 5 to 50% by vol.

22. The organic electroluminescent device according to claim 16, wherein the proportion of phosphorescent compound A in the layer is 12 to 20% by vol.

23. The organic electroluminescent device according to claim 16, wherein the proportion of phosphorescent compound B in the layer is 1 to 20% by vol.

24. The organic electroluminescent device according to claim 16, wherein the proportion of phosphorescent compound B in the layer is 3 to 10% by vol.

25. The organic electroluminescent device according to claim 16, wherein phosphorescent compound A is a material which is capable of transporting holes and has an HOMO of >−5.9 eV.

26. The organic electroluminescent device according to claim 22, wherein the proportion of phosphorescent compound B in the layer is 4 to 7% by vol. and phosphorescent compound A is a material which is capable of transporting holes and has an HOMO of >−5.5 eV.

27. The organic electroluminescent device according to claim 16, wherein phosphorescent compounds A and B contain at least one atom having an atomic number of greater than 38 and less than 84.

28. The organic electroluminescent device according to claim 16, wherein the phosphorescent compounds A and B contain at least one atom that is copper, molybdenum, tungsten, rhenium, ruthenium, osmium, rhodium, iridium, palladium, platinum, silver, gold or europium, in particular compounds which contain iridium or platinum.

29. The organic electroluminescent device according to claim 16, wherein the phosphorescent compounds A and B contain at least one atom that is iridium or platinum.

30. The organic electroluminescent device according to claim 16, wherein the phosphorescent emitters A and/or B are selected from compounds of the formulae (2) to (5): 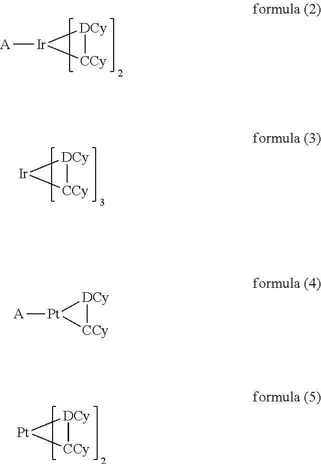
wherein
DCy is, identically or differently on each occurrence, a cyclic group which contains at least one donor atom and which may in turn carry one or more substituents R¹; the groups DCy and CCy are bonded to one another via a covalent bond;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkenyl, alkynyl, alkoxy or thioalkoxy group having 1 to 40 C atoms or a branched or cyclic alkyl, alkenyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which optionally in each case is substituted by one or more radicals R², or an aryloxy or heteroaryloxy group having 5 to 60 aromatic ring atoms, which is optionally substituted by one or more radicals R², or an aralkyl or heteroaralkyl group having 5 to 60 aromatic ring atoms, which is optionally substituted by one or more radicals R², or a combination of these systems; two or more adjacent substituents R¹ optionally forms a mono- or polycyclic, aliphatic or aromatic ring system with one another;
Ar¹ is on each occurrence, identically or differently, an aromatic or heteroaromatic ring system having 5 to 40 aromatic ring atoms, which is optionally substituted by one or more radicals R²;
R² is on each occurrence, identically or differently, H, D or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic or aromatic ring system with one another;
CCy is, identically or differently on each occurrence, a cyclic group which contains a carbon atom via which the cyclic group is bonded to the metal and which may in turn carry one or more substituents R¹;
A is, identically or differently on each occurrence, a monoanionic, bidentate-chelating ligand.

31. The organic electroluminescent device according to claim 30, wherein
DCy is, identically or differently on each occurrence, a cyclic group which contains at least nitrogen, carbon in the form of a carbene or phosphorus, via which the cyclic group is bonded to the metal, and which may in turn carry one or more substituents R¹; the groups DCy and CCy are bonded to one another via a covalent bond; and
A is, identically or differently on each occurrence, a diketonate ligand or a picolinate ligand.

32. The organic electroluminescent device according to claim 16, wherein the group Ar represents an aromatic ring system having 6 to 40 aromatic ring atoms which is built up only from phenyl and/or naphthyl groups, but does not contain any larger aromatic ring systems.

33. The organic electroluminescent device according to claim 16, wherein the group Ar represents an aromatic ring system having 6 to 40 aromatic ring atoms which is built up only from phenyl groups, but does not contain any larger aromatic ring systems.

34. The organic electroluminescent device according to claim 16, wherein the radicals R¹ are selected, identically or differently on each occurrence, from the group consisting of H, D, F, C(═O)Ar¹, P(═O)(Ar¹)₂, S(═O)Ar¹, S(═O)₂Ar¹, a straight-chain alkyl group having 1 to 4 C atoms or a branched or cyclic alkyl group having 3 to 5 C atoms, each of which is optionally substituted by one or more radicals R², where one or more H atoms is optionally replaced by F, or an aromatic ring system having 6 to 24 aromatic ring atoms, which is optionally substituted by one or more radicals R², or a combination of these systems; two or more adjacent substituents R¹ here may also form a mono- or polycyclic, aliphatic or aromatic ring system with one another.

35. The organic electroluminescent device according to claim 17, wherein the aromatic ketone, the aromatic phosphine oxide, the aromatic sulfone or the aromatic sulfoxide is selected from compounds of the formulae (6) to (30): 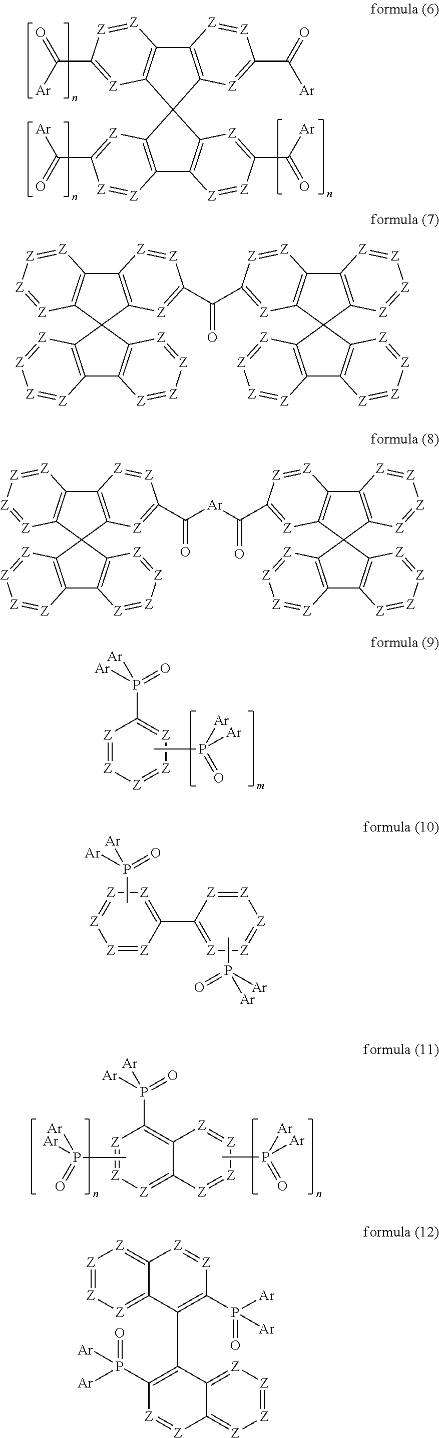 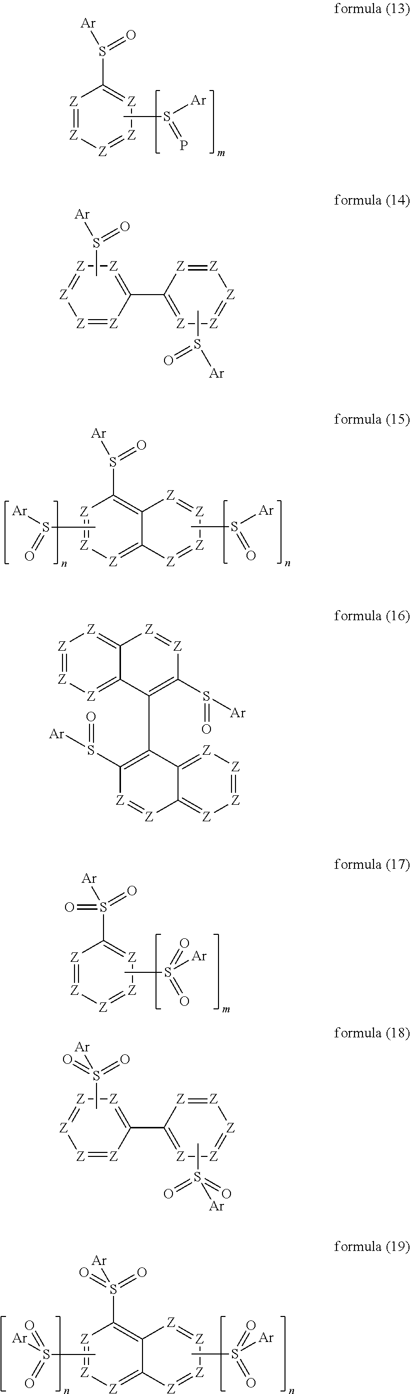 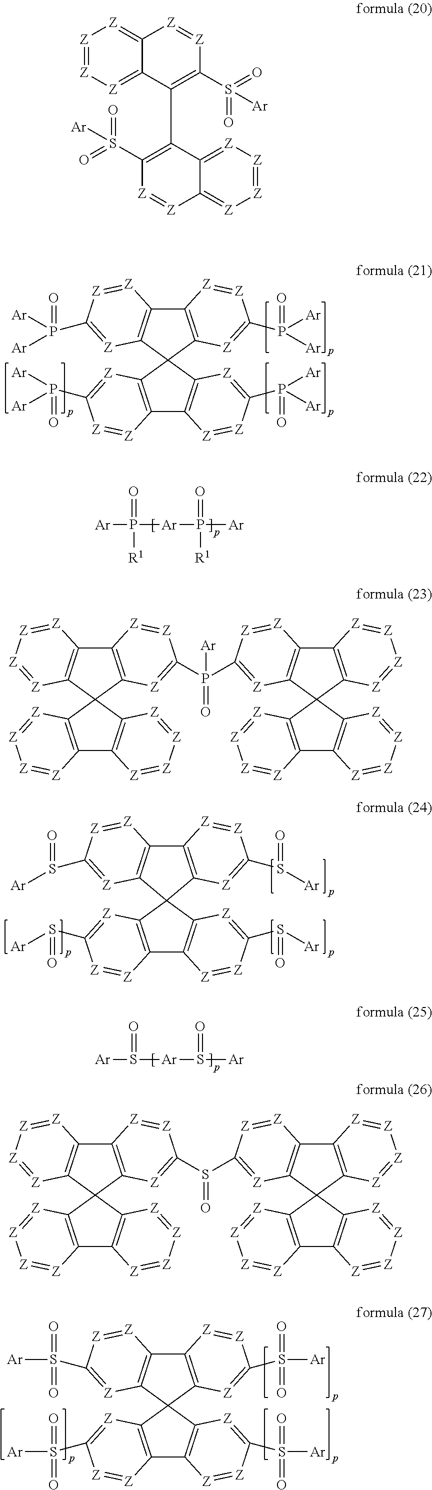 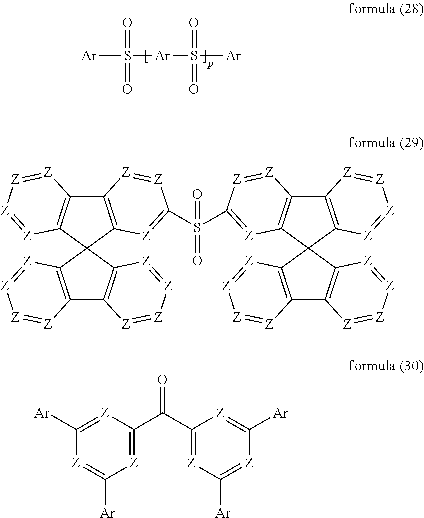
wherein
Ar is on each occurrence, identically or differently, an aromatic or heteroaromatic ring system having 5 to 80 aromatic ring atoms, which optionally in each case is substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkenyl, alkynyl, alkoxy or thioalkoxy group having 1 to 40 C atoms or a branched or cyclic alkyl, alkenyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which optionally in each case is substituted by one or more radicals R², or an aryloxy or heteroaryloxy group having 5 to 60 aromatic ring atoms, which is optionally substituted by one or more radicals R², or an aralkyl or heteroaralkyl group having 5 to 60 aromatic ring atoms, which is optionally substituted by one or more radicals R², or a combination of these systems; two or more adjacent substituents R¹ optionally forms a mono- or polycyclic, aliphatic or aromatic ring system with one another;
Ar¹ is on each occurrence, identically or differently, an aromatic or heteroaromatic ring system having 5 to 40 aromatic ring atoms, which is optionally substituted by one or more radicals R²;
R² is on each occurrence, identically or differently, H, D or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic or aromatic ring system with one another;
Z is, identically or differently on each occurrence, CR¹ or N, where a maximum of 3 symbols Z per ring stand for N;
m is 1, 2, 3, 4 or 5;
n is, identically or differently on each occurrence, 0, 1, 2, 3 or 4; and
p is on each occurrence, identically or differently, 0 or 1.

36. A process for the production of the organic electroluminescent device according to claim 16, which comprises applying one or more layers by means of a sublimation process and/or in that one or more layers are applied by means of the OVPD (organic vapour phase deposition) process or with the aid of carrier-gas sublimation and/or in that one or more layers are produced from solution, or by means of a printing process.

37. A mixture comprising
(A) at least one phosphorescent compound A,
(B) at least one phosphorescent compound B which is different from compound A, and
(C) at least one aromatic ketone, aromatic phosphine oxide, aromatic sulfoxide or aromatic sulfone.

38. The mixture as claimed in claim 37, wherein the at least one aromatic ketone, aromatic phosphine oxide, aromatic sulfoxide or aromatic sulfone, is a compound of the formula (1) 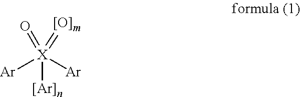
X is C, P or S;
Ar is on each occurrence, identically or differently, an aromatic or heteroaromatic ring system having 5 to 80 aromatic ring atoms, which optionally in each case is substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkenyl, alkynyl, alkoxy or thioalkoxy group having 1 to 40 C atoms or a branched or cyclic alkyl, alkenyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or an aromatic or heteroaromatic ring system having 5 to 60 aromatic ring atoms, which optionally in each case is substituted by one or more radicals R², or an aryloxy or heteroaryloxy group having 5 to 60 aromatic ring atoms, which is optionally substituted by one or more radicals R², or an aralkyl or heteroaralkyl group having 5 to 60 aromatic ring atoms, which is optionally substituted by one or more radicals R², or a combination of these systems; two or more adjacent substituents R¹ optionally forms a mono- or polycyclic, aliphatic or aromatic ring system with one another;
Ar¹ is on each occurrence, identically or differently, an aromatic or heteroaromatic ring system having 5 to 40 aromatic ring atoms, which is optionally substituted by one or more radicals R²;
R² is on each occurrence, identically or differently, H, D or an aliphatic, aromatic and/or heteroaromatic hydrocarbon radical having 1 to 20 C atoms, in which, in addition, H atoms is optionally replaced by F; two or more adjacent substituents R² here may also form a mono- or polycyclic, aliphatic or aromatic ring system with one another;
n is 0 for X═C or S and is 1 for X═P;
m is 0 for X═C or P and is 0 or 1 for X═S.

39. A solution or formulation comprising at least one mixture according to claim 37.
